(19) United States
(12) Patent Application Publication
(10) Pub. No.: US 2012/0168970 A1
(43) Pub. Date: Jul. 5, 2012

(54) SPACER FORMATION FILM, METHOD OF MANUFACTURING SEMICONDUCTOR WAFER BONDING PRODUCT, SEMICONDUCTOR WAFER BONDING PRODUCT AND SEMICONDUCTOR DEVICE

(76) Inventors: Toshihiro Sato, Shinagawa-ku (JP); Masakazu Kawata, Shinagawa-ku (JP); Masahiro Yoneyama, Shinagawa-ku (JP); Toyosei Takahashi, Shinagawa-ku (JP); Hirohisa Dejima, Shinagawa-ku (JP); Fumihiro Shiraishi, Shinagawa-ku (JP)

(21) Appl. No.: 13/496,354

(22) PCT Filed: Sep. 13, 2010
(86) PCT No.: PCT/JP2010/065738

§ 371 Date: Mar. 15, 2012

(30) Foreign Application Priority Data
Sep. 16, 2009 (JP) 2009215056
Sep. 16, 2009 (JP) 2009215057

(51) Int. Cl. H01L 23/544; H01L 23/12; B32B 7/02; H01L 21/50

(52) U.S. Cl. 257/797; 438/116; 257/798; 428/213; 257/E21.499; 257/E23.179; 257/E23.003

(57) ABSTRACT

A method of manufacturing a semiconductor wafer bonding product according to the present invention includes: a step of preparing a spacer formation film including a support base having a sheet-like shape and a spacer formation layer provided on the support base and having photosensitivity; a step of attaching the spacer formation layer to a semiconductor wafer having one surface from a side of the one surface; a step of forming a spacer by subjecting exposure and development to the spacer formation layer to be patterned and removing the support base; a step of bonding a transparent substrate to a region of the spacer, with which the removed support base made contact, so as to be included within the region. This makes it possible to manufacture a semiconductor wafer bonding product in which the semiconductor wafer and the transparent substrate are bonded together through the spacer uniformly and reliably.

### TECHNICAL FIELD

The present invention relates to a spacer formation film, a method of manufacturing a semiconductor wafer bonding product, a semiconductor wafer bonding product and a semiconductor device.

### RELATED ART

Semiconductor devices represented by photo receiving devices such as a CMOS image sensor and a CCD image sensor are known. In general, such a semiconductor device includes a semiconductor substrate provided with a light receiving portion, a spacer provided on the semiconductor substrate at a side of the light receiving portion and formed so as to surround the light receiving portion, and a transparent substrate bonded to the semiconductor substrate via the spacer.

A method of manufacturing such a semiconductor device generally includes: a step of attaching a bonding film (spacer formation layer) having an electron beam curable property to a semiconductor wafer on which a plurality of light receiving portions are provided; a step of selectively irradiating the bonding film with an electron beam via a mask to expose the bonding film; a step of developing the exposed bonding film to form a spacer (spacer substrate); a step of bonding a transparent substrate to the thus formed spacer to obtain a semiconductor product (hereinbelow, it will be referred to as “semiconductor wafer bonding product”); and a step of dicing the semiconductor wafer bonding product to obtain semiconductor devices (see, for example, Patent Document 1).

However, according to such a conventional method, since a surface of the bonding film opposite to the semiconductor wafer is exposed during the exposure step, foreign substances such as dust are likely to adhere to the bonding film. Such foreign substances, which have once adhered to the bonding film, are difficult to be removed therefrom. Consequently, there is a problem in that the adhered foreign substances disturb the exposure of the bonding film, which causes lowering of a dimensional accuracy of the spacer.

Further, there is also a problem in that the mask is attached to the bonding film during the exposure step. In order to prevent the mask from being attached to the bonding film, it may be conceived that a distance (clearance) therebetween makes large. However, in the case where the distance between the mask and the bonding film makes large, an image to be formed from the exposure light, with which the bonding film is irradiated through the mask, becomes dim. This causes indistinctness of a boundary between an exposed region and a non-exposed region or lowering of a positional accuracy of the boundary. As a result, it becomes difficult to form the spacer in a sufficient dimensional accuracy.

### PRIOR ART DOCUMENT

### Patent Document

Patent Document 1: JP-A 2008-91399.

### SUMMARY OF THE INVENTION

It is an object of the present invention to provide a spacer formation film and a method of manufacturing a semiconductor wafer bonding product each of which can manufacture a semiconductor wafer bonding product in which a semiconductor wafer and a transparent substrate are bonded together through a spacer having an excellent dimensional accuracy, and to provide a semiconductor wafer bonding product and a semiconductor device each having superior reliability.

In order to achieve such an object, the present invention includes the following features (1) to (18).

(1) A spacer formation film, comprising:

a support base having a sheet-like shape; and

a spacer formation layer provided on the support base and having a photo curable property, the spacer formation layer capable of forming a spacer to be provided between a transparent substrate and a semiconductor wafer by being exposed and developed,

wherein in the case where an average thickness of the support base is defined as t₁ (μm), an average thickness of the spacer formation layer is defined as t₂ (μm), an absorbance index of the support base within wavelength band of visible light is defined as α_{V1} (1/μm) and an absorbance index of the spacer formation layer within the wavelength band of the visible light is defined as α_{V2} (1/μm), each of the following relational expressions <1> to <4> is satisfied.

α_{V1}×t₁+α_{V2}×t₂≦−log₁₀(0.2) <1>

5≦t₁≦200 <2>

5≦t₂≦400 <3>

10≦t₁+t₂≦405 <4>

(2) The spacer formation film according to the above feature (1), wherein in the case where an amount of the visible light incidence into the support base is defined as I_{V0}, an amount of the visible light passed through the support base is defined as I_{V1} and an amount of the visible light further passed through the spacer formation layer is defined as I_{V2}, each of the following relational expressions <5> to <7> is satisfied.

I_{V1}/I_{V0}≧0.2 <5>

I_{V2}/I_{V1}≧0.2 <6>

I_{V2}/I_{V0}≧0.2 <7>

(3) The spacer formation film according to the above feature (1) or (2), wherein in the case where an absorbance index of the support base within wavelength band of an exposure light used in the exposure is defined as α_{E1} (1/μm) and an absorbance index of the spacer formation layer within the wavelength band of the exposure light is defined as α_{E2} (1/μm), each of the following relational expressions <8> to <11> is satisfied.

α_{E1}×t₁+α_{E2}×t₂≦−log₁₀(0.2) <8>

5≦t₁≦100 <9>

5≦t₂≦350 <10>

10≦t₁+t₂≦400 <11>

(4) A spacer formation film, comprising:

a support base having a sheet-like shape; and

a spacer formation layer provided on the support base and having a photo curable property, the spacer formation layer capable of forming a spacer provided between a transparent substrate and a semiconductor wafer by being exposed and developed,

wherein in the case where an average thickness of the support base is defined as t₁ (μm), an average thickness of the spacer formation layer is defined as t₂ (μm), an absorbance index of the support base within wavelength band of an exposure light used in the exposure is defined as α_{E1} (1/μm) and an absorbance index of the spacer formation layer within the wavelength band of the exposure light is defined as α_{E2} (1/μm), each of the following relational expressions <8> to <11> is satisfied.

α_{E1}×t₁+α_{E2}×t₂≦−log₁₀(0.2) <8>

5≦t₁≦100 <9>

5≦t₂≦350 <10>

10≦t₁+t₂≦400 <11>

(5) The spacer formation film according to the above feature (3) or (4), wherein in the case where an amount of the exposure light incidence into the support base is defined as I_{E0}, an amount of the exposure light passed through the support base is defined as I_{E1} and an amount of the exposure light further passed through the spacer formation layer is defined as I_{E2}, each of the following relational expressions <12> to <14> is satisfied.

I_{E1}/I_{E0}≧0.2 <12>

0.1≦I_{E2}/I_{E1}≦0.9 <13>

0.1≦I_{E2}/I_{E0}≦0.9 <14>

(6) The spacer formation film according to any one of the above features (1) to (5), wherein the support base is formed of a resin material as a major component thereof.

(7) The spacer formation film according to the above feature (6), wherein the resin material comprises polyethylene, polypropylene or polyethylene terephthalate.

(8) The spacer formation film according to any one of the above features (1) to (7), wherein the spacer formation layer is formed of a material containing an alkali soluble resin, a thermosetting resin and a photo initiator.

(9) The spacer formation film according to the above feature (8), wherein the alkali soluble resin is a (meth)acryl-modified phenol resin.

(10) The spacer formation film according to the above feature (8) or (9), wherein the thermosetting resin is an epoxy resin.

(11) A method of manufacturing a semiconductor wafer bonding product, comprising:

a step of preparing the spacer formation film defined by any one of the above features (1) to (10);

a step of attaching the spacer formation layer to a semiconductor wafer having one surface from a side of the one surface;

a step of subjecting the spacer formation layer to an exposure treatment by being selectively irradiated with an exposure light through the support base;

a step of removing the support base;

a step of forming a spacer by subjecting the spacer formation layer to a developing treatment using a developer; and

a step of bonding a transparent substrate to a surface of the spacer opposite to the semiconductor wafer.

(12) A method of manufacturing a semiconductor wafer bonding product, comprising:

a step of preparing the spacer formation film defined by any one of the above features (1) to (10);

a step of attaching the spacer formation layer to a transparent substrate having one surface from a side of the one surface;

a step of subjecting the spacer formation layer to an exposure treatment by being selectively irradiated with an exposure light through the support base;

a step of removing the support base;

a step of forming a spacer by subjecting the spacer formation layer to a developing treatment using a developer; and

a step of bonding a semiconductor wafer to a surface of the spacer opposite to the transparent substrate.

(13) The method according to the above feature (11) or (12), wherein when the spacer formation layer is irradiated with the exposure light through the support base, the irradiation of the exposure light is carried out through a mask placed at a side of the support base opposite to the spacer formation layer.

(14) The method according to the above feature (13), wherein when the mask is placed, positioning of the mask is carried out using an alignment mark provided on the mask and an alignment mark provided on the semiconductor wafer or the transparent substrate located at a side of the spacer formation layer opposite to the support base.

(15) The method according to the above feature (13) or (14), wherein a distance between the mask and the support base during the exposure step is preferably in the range of 0 to 2,000 μm.

(16) A semiconductor wafer bonding product manufactured using the method defined by any one of the above features (11) to (15).

(17) A semiconductor wafer bonding product in which a semiconductor wafer and a transparent substrate are bonded together through a spacer formed using the spacer formation film defined by any one of the above features (11) to (15).

(18) A semiconductor device obtained by dicing the semiconductor wafer bonding product defined by the above feature (16) or (17).

### BRIEF DESCRIPTION OF THE DRAWINGS

FIG. 1 is a sectional view showing a semiconductor device according to an embodiment of the present invention.

FIG. 2 is a longitudinal sectional view showing a semiconductor wafer bonding product according to the embodiment of the present invention.

FIG. 3 is a top view showing the semiconductor wafer bonding product shown in FIG. 2.

FIG. 4 is a process chart showing one example of a method of manufacturing the semiconductor device shown in FIG. 1 (or the semiconductor wafer bonding product shown in FIG. 2).

FIG. 5 is a process chart showing the one example of the method of manufacturing the semiconductor device shown in FIG. 1 (or the semiconductor wafer bonding product shown in FIG. 2), which is continued from FIG. 4.

FIG. 6 is a view for explaining the exposure step shown in FIG. 4(d).

FIG. 7 is a graph for explaining light transmission through each of the support base and the spacer formation layer shown in FIG. 4(d).

FIG. 8 is also a graph for explaining light transmission through each of the support base and the spacer formation layer shown in FIG. 4(d).

### MODE FOR CARRYING OUT THE INVENTION

Hereinafter, description will be made on embodiments of the present invention based on the accompanying drawings.

<Semiconductor Device (Image Sensor)>

First, description will be made on a semiconductor device of the present invention.

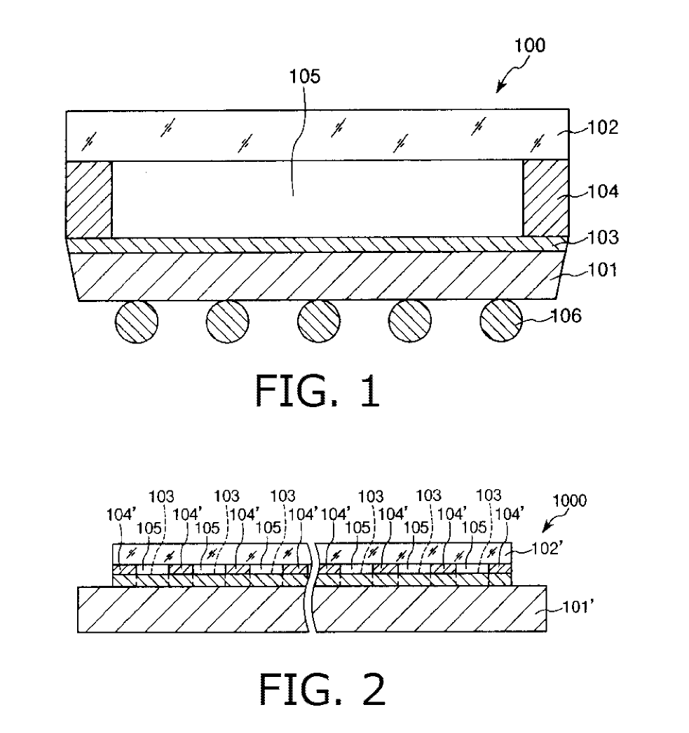

FIG. 1 is a sectional view showing a semiconductor device according to an embodiment of the present invention. In this regard, in the following description, the upper side in FIG. 1 will be referred to as “upper” and the lower side thereof will be referred to as “lower” for convenience of explanation.

A semiconductor device 100 shown in FIG. 1 is obtained by dicing a semiconductor wafer bonding product 1000 of the present invention, which will be described below.

As shown in FIG. 1, such a semiconductor device (light receiving device) 100 includes a base substrate 101, a transparent substrate 102 provided so as to face the base substrate 101, a light receiving portion 103 provided on a surface of the base substrate 101, which is located at a side of the transparent substrate 102, a spacer 104 provided between the transparent substrate 102 and the light receiving portion 103, and solder bumps 106 each provided on a surface of the base substrate 101 opposite to the light receiving portion 103.

The base substrate 101 is a semiconductor substrate on which a circuit not shown in FIG. 1 (that is, an individual circuit provided on a semiconductor wafer described below) is provided.

On almost a whole one surface (upper surface) of the base substrate 101, the light receiving portion 103 is provided.

For example, the light receiving portion 103 has a structure in which a light receiving element and a microlens array are formed (stacked) on the base substrate 101 in this order.

Examples of the light receiving element of the light receiving portion 103 include CCD (Charge Coupled Device), a CMOS (Complementary Metal Oxide Semiconductor) image sensor and the like. Such a light receiving portion 103, in which the light receiving element is provided, changes light received by the light receiving portion 103 to electrical signals.

The transparent substrate 102 is provided so as to face the one surface (upper surface) of the base substrate 101 and has a planar size substantially equal to a planar size of the base substrate 101.

Examples of the transparent substrate 102 include an acryl resin substrate, a polyethylene terephthalate resin (PET) substrate, a glass substrate and the like.

The spacer 104 is directly bonded to both the light receiving portion 103 and the transparent substrate 102. In this way, the base substrate 101 and the transparent substrate 102 are bonded together through the spacer 104.

Further, the spacer 104 is provided along an outer edge portion of each of the light receiving portion 103 and the transparent substrate 102, to thereby be of a frame shape. In this way, an air-gap portion 105 is formed (defined) between the light receiving portion 103 and the transparent substrate 102.

Here, the spacer 104 is provided so as to surround a central area of the light receiving portion 103. Therefore, an area of the light receiving portion 103 surrounded by the spacer 104, that is, an area exposed within the air-gap portion 105 can substantially function as a light receiving portion.

The solder bumps 106 have conductivity and are electrically connected to a circuit provided on the lower surface of the base substrate 101. This makes it possible for the electrical signals changed from the light by the light receiving portion 103 to be transmitted to the solder bumps 106.

<Semiconductor Wafer Bonding Product>

Next, description will be made on a semiconductor wafer bonding product.

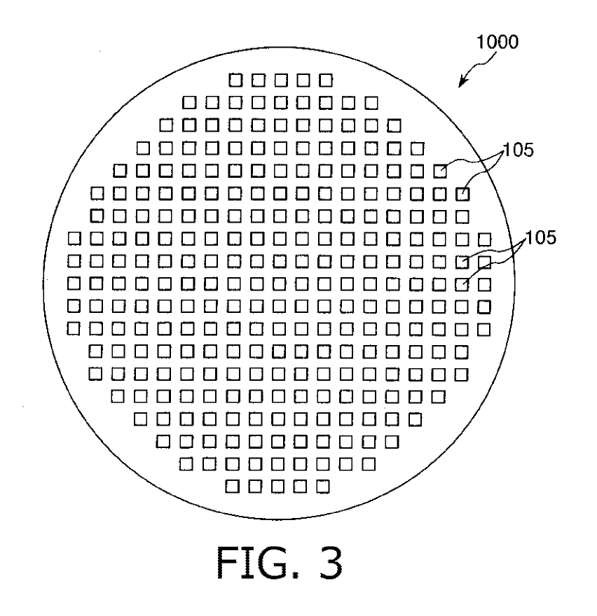

FIG. 2 is a longitudinal sectional view showing the semiconductor wafer bonding product according to the embodiment of the present invention, and FIG. 3 is a top view showing the semiconductor wafer bonding product shown in FIG. 2.

As shown in FIG. 2, a semiconductor wafer bonding product 1000 is constituted from a stacked body in which a semiconductor wafer 101′, a spacer (spacer substrate) 104′ and a transparent substrate 102′ are stacked in this order. Namely, in the semiconductor wafer bonding product 1000, the semiconductor wafer 101′ and the transparent substrate 102′ are bonded together through the spacer 104′

The semiconductor wafer 101′ becomes the base substrate 101 of the semiconductor device 100 described above through a dicing step as described below.

Further, on the semiconductor wafer 101′, formed are a plurality of individual circuits not shown in FIG. 2.

In this regard, on the one surface (upper surface) of the semiconductor wafer 101′, formed is the above mentioned light receiving portion 103 so as to correspond to each of the above individual circuits.

As shown in FIG. 3, the spacer 104′ has a grid-like shape at a planar view thereof and is provided so as to surround each of the individual circuits on the semiconductor wafer 101′ (that is, each light receiving portion 103). Further, the spacer 104′ forms (defines) a plurality of air-gap portions 105 between the semiconductor wafer 101′ and the transparent substrate 102′. Namely, the plurality of air-gap portions 105 are arranged so as to correspond to the plurality of individual circuits described above at a planar view thereof.

This spacer 104′ is a member which becomes the spacer 104 of the semiconductor device 100 described above through the dicing step as described below.

The transparent substrate 102′ is bonded to the semiconductor substrate 101′ via the spacer 104′.

This transparent substrate 102′ is a member which becomes the transparent substrate 102 of the semiconductor device 100 described above through the dicing step as described below.

Such a semiconductor wafer bonding product 1000 is diced as described below so that a plurality of the semiconductor devices 100 can be obtained.

<Method of Manufacturing Semiconductor Device (Semiconductor Wafer Bonding Product)>

Next, description will be made on a preferred embodiment of a method of manufacturing a semiconductor device (semiconductor wafer bonding product) of the present invention. In this regard, hereinbelow, the description will be made on the method of manufacturing a semiconductor device according to the present invention as one example of a case of manufacturing the semiconductor device 100 and semiconductor wafer bonding product 1000 described above.

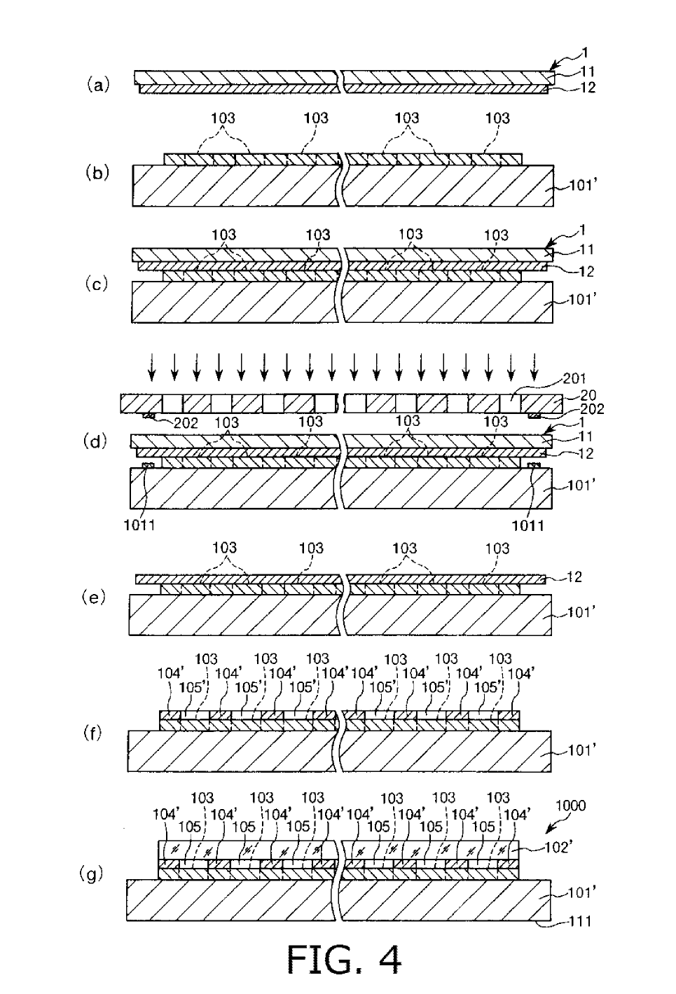

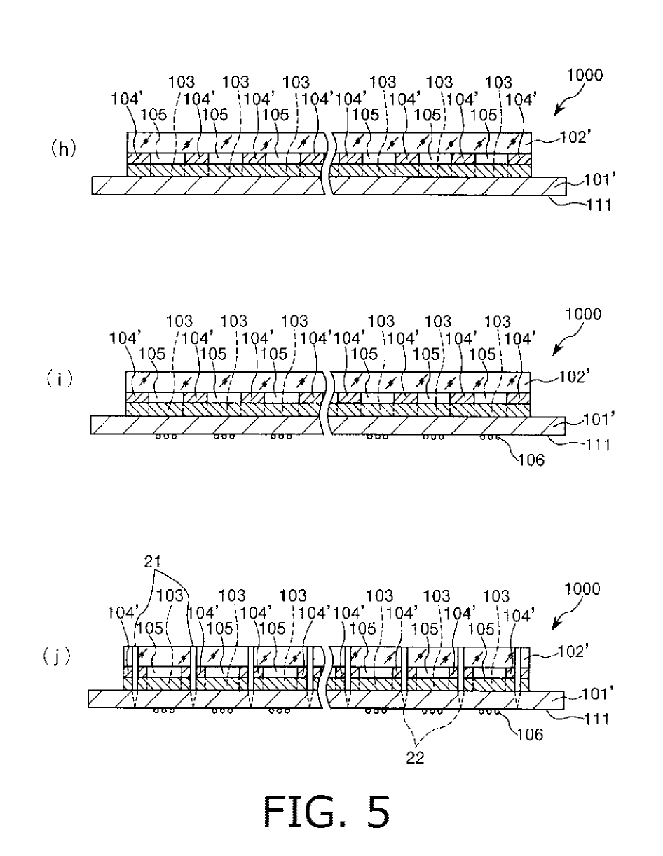

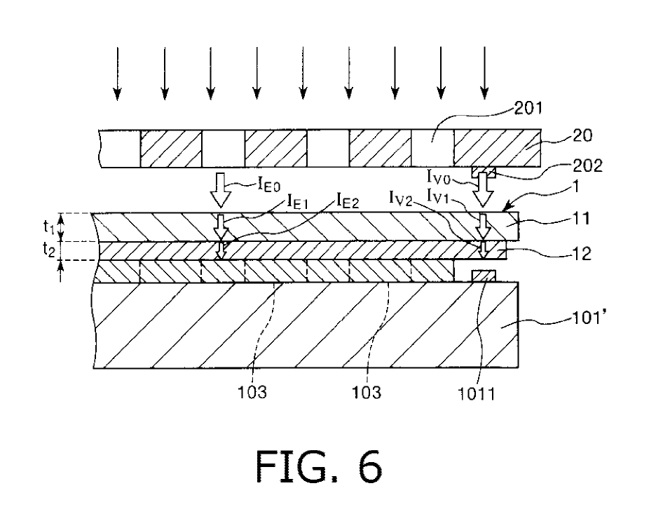

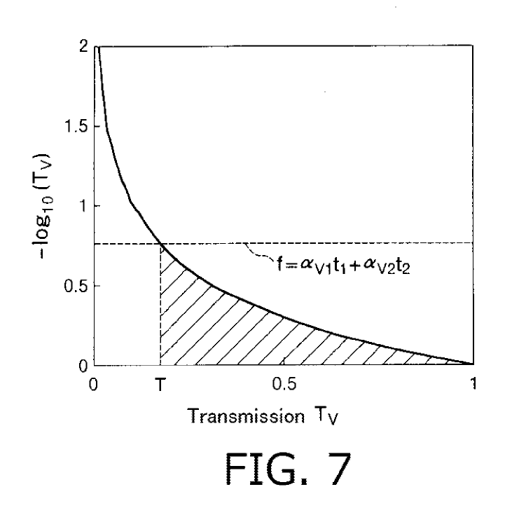

FIGS. 4 and 5 are process charts each showing one example of the method of manufacturing the semiconductor device shown in FIG. 1 (or the semiconductor wafer bonding product shown in FIG. 2), FIG. 6 is a view for explaining the exposure step shown in FIG. 4(d) and FIG. 7 is a view for explaining light transmission through each of the support base and the spacer formation layer shown in FIG. 4(d).

The method of manufacturing the semiconductor device 100 includes [A] a step of producing (manufacturing) the semiconductor wafer bonding product 1000 and [B] a step of dicing the semiconductor wafer bonding product 1000.

Here, a method of producing the semiconductor wafer bonding product 1000 (that is, the above step [A]) includes <<A1>> a step of attaching a spacer formation layer 12 to the semiconductor wafer 101′, <<A2>> a step of forming the spacer 104′ by selectively removing the spacer formation layer 12, <<A3>> a step of bonding the transparent substrate 102′ to a surface of the spacer 104′ opposite to the semiconductor wafer 101′ and <<A4>> a step of subjecting the lower surface of the semiconductor wafer 101′ to a predetermined processing or treatment.

Hereinbelow, each of the steps of the method of manufacturing the semiconductor device 100 will be described in detail one after another.

[A] Step of Producing Semiconductor Wafer Bonding Product 1000

<<A1>> Step of Attaching Spacer Formation Layer 12 to Semiconductor Wafer 101′

A1-1

First, as shown in FIG. 4(a), a spacer formation film 1 is prepared.

This spacer formation film 1 includes a support base 11 and the spacer formation layer 12 provided on the support base 11.

The support base 11 has a sheet-like shape and has a function for supporting the spacer formation layer 12.

This support base 11 has optical transparency.

This makes it possible for the spacer formation layer to be exposed with an exposure light through the support base 11 in a state that the support base 11 is attached to the spacer formation layer 12 in an exposure treatment during the step <<A2>> described below.

Especially, there is a predetermined relationship between a thickness and an absorbance index of the support base 11 and a thickness and an absorbance index of the spacer formation layer 12 (that is, each of relational expressions <1> to <4> described below is satisfied). In this regard, the thickness and the absorbance index of each of the support base 11 and the spacer formation layer 12 will be described together with description of the step <<A2>> described below.

A constituent material of such a support base 11 is not limited to a specific kind, as long as the support base 11 has the above mentioned function of supporting the spacer formation layer 12 and satisfies the relational expressions <1> to <4> described below. Examples of the constituent material include polyethylene terephthalate (PET), polypropylene (PP), polyethylene (PE) and the like. Among them, it is preferable to use the polyethylene terephthalate (PET) as the constituent material of the support base 11 from the viewpoint that the support base 11 can exhibit both the optical transparency and rupture strength in excellent balance.

On the other hand, the spacer formation layer 12 has a bonding property with respect to a surface of the semiconductor wafer 101′. This makes it possible to bond (attach) the spacer formation layer 12 and the semiconductor wafer 101′ together.

Further, the spacer formation layer 12 has a photo curable property. This makes it possible to pattern the spacer formation layer 12 so as to have a predetermined shape by the exposure treatment and a developing treatment, to thereby form the spacer 104′ during the step <<A2>> described below.

Furthermore, the spacer formation layer 12 also has a thermal curable property. This makes it possible to bond the spacer 104′ and the transparent substrate 102′ together during a step <<A3>> described below.

The spacer formation layer 12 is not limited to a specific one, as long as it can have the bonding property, the photo curable property and the thermal curable property as described above, and satisfy the relational expressions <1> to <4> described below. It is preferred that the spacer formation layer 12 is constituted from a material containing an alkali soluble resin, a thermosetting resin and a photo initiator (hereinbelow, this material is referred to as “resin composition”).

Hereinbelow, description will be made on each of components of the resin composition in detail.

(Alkali Soluble Resin)

Examples of the alkali soluble resin include: a novolac resin such as a cresol-type novolac resin, a phenol-type novolac resin, a bisphenol A-type novolac resin, a bisphenol F-type novolac resin, a catechol-type novolac resin, a resorcinol-type novolac resin and a pyrogallol-type novolac resin; a phenol aralkyl resin; a hydroxystyrene resin; an acryl-based resin such as a methacrylic acid resin and a methacrylic acid ester resin; a cyclic olefin-based resin containing hydroxyl groups, carboxyl groups and the like; a polyamide-based resin; and the like. These alkali soluble resins may be used singly or in combination of two or more of them.

In this regard, concrete examples of the polyamide-based resin include: a resin containing at least one of a polybenzoxazole structure and a polyimide structure, and hydroxyl groups, carboxyl groups, ether groups or ester groups in a main chain or branch chains thereof; a resin containing a polybenzoxazole precursor structure; a resin containing a polyimide precursor structure; a resin containing a polyamide acid ester structure; and the like.

The spacer formation layer 12 containing such an alkali soluble resin can have an alkali developable property capable of reducing adverse effect on environment.

Among these alkali soluble resins, it is preferable to use an alkali soluble resin containing both alkali soluble groups, which contribute to the alkali developing, and double bonds.

Examples of the alkali soluble groups include a hydroxyl group, a carboxyl group and the like. The alkali soluble groups can also contribute to a thermal curing reaction in addition to the alkali developing. Further, since the alkali soluble resin contains the double bonds, it also can contribute to a photo curing reaction.

Examples of such a resin containing alkali soluble groups and double bonds include a curable resin which can be cured by both light and heat. Concrete examples of the curable resin include a thermosetting resin containing photo reaction groups such as an acryloyl group, a methacryloyl group and a vinyl group; a photo curable resin containing thermal reaction groups such as a phenolic hydroxyl group, an alcoholic hydroxyl group, a carboxyl group and an anhydride group; and the like.

By using the curable resin capable of being cured by both light and heat as the alkali soluble resin, it is possible to improve compatibility of the alkali soluble resin with respect to a thermosetting resin described below. As a result, strength of the spacer formation layer 12 after being cured, that is, the spacer 104′ can be improved.

In this regard, it is to be noted that the photo curable resin containing thermal reaction groups may further have other thermal reaction groups such as an epoxy group, an amino group and a cyanate group. Concrete examples of the photo curable resin having such a chemical structure include a (meth)acryl-modified phenol resin, an acryl acid polymer containing (meth)acryloyl groups, an (epoxy)acrylate containing carboxyl groups, and the like. Further, the photo curable resin may be a thermoplastic resin such as an acryl resin containing carboxyl groups.

Among the above resins each containing alkali soluble groups and double bonds (that is, the curable resins which can be cured by both light and heat), it is preferable to use the (meth)acryl-modified phenol resin.

By using the (meth)acryl-modified phenol resin, since the resin contains the alkali soluble groups, when the resin which has not reacted is removed during a developing treatment, an alkali solution having less adverse effect on environment can be used as a developer instead of an organic solvent which is normally used. Further, since the resin contains the double bonds, these double bonds contribute to the curing reaction. As a result, it is possible to improve heat resistance of the resin composition.

Furthermore, by using the (meth)acryl-modified phenol resin, it is possible to reliably reduce a degree of warp of the semiconductor wafer bonding product 1000. From the viewpoint of such a fact, it is also preferable to use the (meth)acryl-modified phenol resin.

Examples of the (meth)acryl-modified phenol resin include a (meth)acryloyl-modified bisphenol resin or a (meth)acryloyl-modified phenol novolak resin obtained by reacting hydroxyl groups contained in bisphenols of phenol novolaks with epoxy groups of compounds containing the epoxy groups and (meth)acryloyl groups.

Further, as another (meth)acryloyl-modified bisphenol resin, exemplified is a compound introducing a dibasic acid into a molecular chain of a (meth)acryloyl-modified epoxy resin in which (meth) acryloyl groups are bonded to both ends of an epoxy resin, the compound obtained by bonding one of carboxyl groups of the dibasic acid to one hydroxyl group of the molecular chain of the (meth)acryloyl-modified epoxy resin via an ester bond. In this regard, it is to be noted that this compound has one or more repeating units of the epoxy resin and one or more dibasic acids introduced into the molecular chain.

Such a compound can be synthesized by reacting epoxy groups existing both ends of an epoxy resin obtained by polymerizing epichlorohydrin and polyalcohol with (meth)acrylic acid to obtain a (meth)acryloyl-modified epoxy resin in which acryloyl groups are introduced into both the ends of the epoxy resin, and then reacting hydroxyl groups of a molecular chain of the (meth)acryloyl-modified epoxy resin with an anhydride of a dibasic acid to form an ester bond together with one of carboxyl groups of the dibasic acid.

Here, in the case of using the thermosetting resin containing photo reaction groups, a modified ratio (substitutional ratio) of the photo reaction groups is not limited to a specific value, but is preferably in the range of about 20 to 80%, and more preferably about 30 to 70% with respect to total reaction groups of the resin containing alkali soluble groups and double bonds. If the modified ratio of the photo reaction groups falls within the above range, it is possible to provide a resin composition having an excellent developing property.

On the other hand, in the case of using the photo curable resin containing thermal reaction groups, a modified ratio (substitutional ratio) of the thermal reaction groups is not limited to a specific value, but is preferably in the range of about 20 to 80%, and more preferably in the range of about 30 to 70% with respect to total reaction groups of the resin containing alkali soluble groups and double bonds. If the modified ratio of the thermal reaction groups falls within the above range, it is possible to provide a resin composition having an excellent developing property.

Further, in the case where the resin having alkali soluble groups and double bonds is used as the alkali soluble resin, a weight-average molecular weight of the resin is not limited to a specific value, but is preferably 30,000 or less, and more preferably in the range of about 5,000 to 15,000. If the weight-average molecular weight falls within the above range, it is possible to further improve a film forming property of the resin composition in forming the spacer formation layer onto the support base 11.

Here, the weight-average molecular weight of the alkali soluble rein can be measured using, for example, a gel permeation chromatographic method (GPC). That is, according to such a method, the weight-average molecular weight can be calculated based on a calibration curve which has been, in advance, made using styrene standard substances. In this regard, it is to be noted that the measurement is carried out using tetrahydrofuran (THF) as a measurement solvent at a measurement temperature of 40° C.

Further, an amount of the alkali soluble resin contained in the resin composition is not limited to a specific value, but is preferably in the range of about 15 to 60 wt %, and more preferably in the range of about 20 to 50 wt % with respect to a total amount of the resin composition. In this regard, in the case where the resin composition contains a filler described below, the amount of the alkali soluble resin may be preferably in the range of about 10 to 80 wt %, and more preferably in the range of about 15 to 70 wt % with respect to resin components contained in the resin composition (total components excluding the filler).

If the amount of the alkali soluble resin falls within the above range, a mixing balance between the alkali soluble resin and the thermosetting resin described below can be optimized in the spacer formation layer 12. Therefore, it is possible to improve patterning resolution and development of the spacer formation layer 12 in the exposure treatment and the developing treatment during the step <<A2>> described below. Further, even after the spacer formation layer 12 has been subjected to the above treatments, the spacer formation layer 12, that is, the spacer 104′ can excellently maintain the bonding property thereof.

Meanwhile, if the amount of the alkali soluble resin is less than the above lower limit value, there is a case that an effect of improving compatibility with other components (e.g., the photo curable resin described below) contained in the resin composition is lowered. On the other hand, if the amount of the alkali soluble resin exceeds the upper limit value, there is a fear that the developing property of the resin composition or patterning resolution of the spacer 104′ formed by a photo lithography technique is lowered.

(Thermosetting Resin)

Examples of the thermosetting resin include: a novolac-type phenol resin such as a phenol novolac resin, a cresol novolac resin and a bisphenol A novolac resin; a phenol resin such as a resol phenol resin; a bisphenol-type epoxy resin such as a bisphenol A epoxy resin and a bisphenol F epoxy resin; a novlolac-type epoxy resin such as a novolac epoxy resin and a cresol novolac epoxy resin; an epoxy resin such as a biphenyl-type epoxy resin, a stilbene-type epoxy resin, a triphenol methane-type epoxy resin, an alkyl-modified triphenol methane-type epoxy resin, a triazine chemical structure-containing epoxy resin and a dicyclopentadiene-modified phenol-type epoxy resin; an urea resin; a resin having triazine rings such as a melamine resin; an unsaturated polyester resin; a bismaleimide resin; a polyurethane resin; a diallyl phthalate resin; a silicone resin; a resin having benzooxazine rings; a cyanate ester resin; an epoxy-modified-siloxane; and the like. These thermosetting resins may be used singly or in combination of two or more of them.

The spacer formation layer 12 containing such a thermosetting resin can exhibit a bonding property due to curing thereof, even after it has been exposed and developed. For this reason, after the spacer formation layer 12 has been bonded to the semiconductor wafer 101′, and exposed and developed, the transparent substrate 10 can be bonded to the spacer formation layer 12 (that is, the spacer 104′) by thermal bonding.

In this regard, in the case where the curable resin which can be cured by heat is used as the above alkali soluble resin, a resin other than the curable resin is selected as the thermosetting resin.

Further, among the thermosetting resins, it is preferable to use the epoxy resin. This makes it possible to improve heat resistance of the spacer formation layer 12 after being cured (that is, the spacer 104′) and adhesion of the transparent substrate 102 thereto.

Furthermore, in the case of using the epoxy resin as the thermosetting resin, it is preferred that an epoxy resin in a solid state at room temperature (in particular, bisphenol-type epoxy resin) and an epoxy resin in a liquid state at room temperature (in particular, silicone-modified epoxy resin in a liquid state at room temperature) are used in combination as the epoxy resin. This makes it possible to obtain a spacer formation layer 12 having excellent flexibility and resolution, while maintaining heat resistance thereof.

An amount of the thermosetting resin contained in the resin composition is not limited to a specific value, but preferably in the range of about 10 to 40 wt %, and more preferably in the range of about 15 to 35 wt % with respect to the total amount of the resin composition. If the amount of the thermosetting resin is less than the above lower limit value, there is a case that an effect of improving the heat resistance of the spacer formation layer 12 by the thermosetting resin is lowered. On the other hand, if the amount of the thermosetting resin exceeds the above upper limit value, there is a case that an effect of improving toughness of the spacer formation layer 12 by the thermosetting resin is lowered.

Further, in the case of using the above epoxy resin as the thermosetting resin, it is preferred that the thermosetting resin further contains the phenol novolac resin in addition to the epoxy resin. Addition of the phenol novolac resin makes it possible to improve the resolution of the spacer formation layer 12. Furthermore, in the case where the resin composition contains both the epoxy resin and the phenol novolac resin as the thermosetting resin, it is also possible to obtain an advantage that the thermal curable property of the epoxy resin can be further improved, to thereby make the strength of the spacer 104 to be formed higher.

(Photo Initiator)

Examples of the photo initiator include benzophenone, acetophenone, benzoin, benzoin isobutyl ether, benzoin methyl benzoic acid, benzoin benzoic acid, benzoin methyl ether, benzyl phenyl sulfide, benzyl, dibenzyl, diacetyl and the like.

The spacer formation layer 12 containing such a photo initiator can be more effectively patterned due to photo polymerization thereof.

An amount of the photo initiator contained in the resin composition is not limited to a specific value, but is preferably in the range of about 0.5 to 5 wt %, and more preferably in the range of about 0.8 to 3.0 wt % with respect to the total amount of the resin composition. If the amount of the photo initiator is less than the above lower limit value, there is a fear that an effect of starting the photo polymerization of the spacer formation layer 12 is not exhibited sufficiently. On the other hand, if the amount of the photo initiator exceeds the above upper limit value, reactivity of the spacer formation layer 12 is extremely improved, and therefore there is a fear that storage stability or resolution thereof is lowered.

(Photo Polymerizable Resin)

It is preferred that the resin composition constituting the spacer formation layer 12 also contains a photo polymerizable resin in addition to the above components. This makes it possible to further improve a patterning property of the spacer formation layer 12 to be obtained.

In this regard, in the case where the curable resin which can be cured by light is used as the above alkali soluble resin, a resin other than the curable resin is selected as the photo polymerizable resin.

Examples of the photo polymerizable resin include: but are not limited to, an unsaturated polyester; a (meth)acryl-based compound such as a (meth)acryl-based monomer and a (meth)acryl-based oligomer each containing one or more acryloyl groups or one or more methacryloyl groups in one molecule thereof; a vinyl-based compound such as styrene; and the like. These photo polymerizable resins may be used alone or in combination of two or more of them.

Among them, a photo polymerizable resin containing the (meth)acryl-based compound as a major component thereof is preferable. This is because a curing rate of the (meth)acryl-based compound is fast when being exposed with light, and therefore it is possible to appropriately pattern the resin with a relatively small exposure amount.

Examples of the (meth)acryl-based compound include a monomer of an acrylic acid ester or methacrylic acid ester, and the like. Concretely, examples of the monomer include: a difunctional (meth)acrylate such as ethylene glycol di(meth)acrylate, 1,6-hexanediol di(meth)acrylate, glycerin di(meth)acrylate and 1,10-decanediol di(meth)acrylate; a trifunctional (meth)acrylate such as trimethylol propane tri(meth)acrylate and pentaerythritol tri(meth)acrylate; a tetrafunctional (meth)acrylate such as pentaerythritol tetra(meth)acrylate and ditrimethylol propane tetra(meth)acrylate; a hexafunctional (meth)acrylate such as dipentaerythritol hexa(meth)acrylate; and the like.

Among these (meth)acryl-based compounds, it is preferable to use a (meth)acryl-based polyfunctional monomer. This makes it possible for the spacer 104 to be obtained from the spacer formation layer 12 to exhibit excellent strength. As a result, a semiconductor device 100 provided with the spacer 104 can have a more superior shape keeping property.

In this regard, it is to be noted that, in the present specification, the (meth)acryl-based polyfunctional monomer means a monomer of a (meth)acrylic acid ester containing three or more acryloyl groups or (meth)acryloyl groups.

Further, among the (meth)acryl-based polyfunctional monomers, it is more preferable to use the trifunctional (meth)acrylate or the tetrafunctional (meth)acrylate. This makes it possible to exhibit the above effects more remarkably.

In this regard, in the case of using the (meth)acryl-based polyfunctional monomer, it is preferred that the photo polymerizable resin further contains an epoxy vinyl ester resin. In this case, since the (meth)acryl-based polyfunctional monomer is reacted with the epoxy vinyl ester resin by radical polymerization when exposing the spacer formation layer 12, it is possible to more effectively improve the strength of the spacer 104 to be formed. On the other hand, it is possible to improve solubility of the non-exposed region of the spacer formation layer 12 with the alkali developer when developing it, to thereby reduce residues after the development.

Examples of the epoxy vinyl ester resin include 2-hydroxyl-3-phenoxypropyl acrylate, EPOLIGHT 40E methacryl addition product, EPOLIGHT 70P acrylic acid addition product, EPOLIGHT 200P acrylic acid addition product, EPOLIGHT 80MF acrylic acid addition product, EPOLIGHT 3002 methacrylic acid addition product, EPOLIGHT 3002 acrylic acid addition product, EPOLIGHT 1600 acrylic acid addition product, bisphenol A diglycidyl ether methacrylic acid addition product, bisphenol A diglycidyl ether acrylic acid addition product, EPOLIGHT 200E acrylic acid addition product, EPOLIGHT 400E acrylic acid addition product, and the like.

In the case where the photo polymerizable resin contains the (meth)acryl-based polyfunctional monomer, an amount of the (meth)acryl-based polyfunctional monomer contained in the resin composition is not limited to a specific value, but is preferably in the range of about 1 to 50 wt %, and more preferably in the range of about 5 to 25 wt % with respect to the total amount of the resin composition. This makes it possible to more effectively improve the strength of the spacer formation layer 12 after being exposed, that is, the spacer 104, and thus to more effectively improve the shape keeping property thereof when the transparent substrate 102 is bonded to the semiconductor wafer 101′.

Further, in the case where the photo polymerizable resin contains the epoxy vinyl ester resin in addition to the (meth)acryl-based polyfunctional monomer, an amount of the epoxy vinyl ester resin is not limited to a specific value, but is preferably in the range of about 3 to 30 wt %, and more preferably in the range of about 5 to 15 wt % with respect to the total amount of the resin composition. This makes it possible to more effectively improve the solubility of the non-exposed region of the spacer formation layer 12 by the alkali developer.

Furthermore, it is preferred that the above photo polymerizable resin is of a liquid state at normal temperature. This makes it possible to further improve curing reactivity of the spacer formation layer by light irradiation (e.g., by ultraviolet ray irradiation). In addition, it is possible to easily mix the photo polymerizable resin with the other components (e.g., the alkali soluble resin). Examples of the photo polymerizable resin in the liquid state at the normal temperature include the above ultraviolet curable resin containing the (meth)acryl-based compound as the major component thereof, and the like.

In this regard, it is to be noted that a weight-average molecular weight of the photo polymerizable resin is not limited to a specific value, but is preferably 5,000 or less, and more preferably in the range of about 150 to 3,000. If the weight-average molecular weight falls within the above range, sensitivity of the spacer formation layer 12 becomes specifically higher. Further, the spacer formation layer 12 can also have superior resolution.

Here, the weight-average molecular weight of the photo polymerizable resin can be measured using, for example, the gel permeation chromatographic method (GPC), and is calculated in the same manner as described above.

(Inorganic Filler)

In this regard, it is to be noted that the resin composition constituting the spacer formation layer 12 may also contain an inorganic filler. This makes it possible to further improve the strength of the spacer 104 to be formed from the spacer formation layer 12.

However, in the case where an amount of the inorganic filler contained in the resin composition becomes too large, raised are problems such as adhesion of foreign substances derived from the inorganic filler onto the semiconductor wafer 101′ and occurrence of undercut after developing the spacer formation layer 12. For this reason, it is preferred that the amount of the inorganic filler contained in the resin composition is 9 wt % or less with respect to the total amount of the resin composition.

Further, in the case where the resin composition contains the (meth)acryl-based polyfunctional monomer as the photo polymerizable resin, since it is possible to sufficiently improve the strength of the spacer 104 to be formed from the spacer formation layer 12 due to the addition of the acryl-based polyfunctional monomer, the addition of the inorganic filler to the resin composition can be omitted.

Examples of the inorganic filler include: a fibrous filler such as an alumina fiber and a glass fiber; a needle filler such as potassium titanate, wollastonite, aluminum borate, needle magnesium hydroxide and whisker; a platy filler such as talc, mica, sericite, a glass flake, scaly graphite and platy calcium carbonate; a globular (granular) filler such as calcium carbonate, silica, fused silica, baked clay and non-baked clay; a porous filler such as zeolite and silica gel; and the like. These inorganic fillers may be used alone or in combination of two or more of them. Among them, it is preferable to use the globular (granular) filler or the porous filler.

An average particle size of the inorganic filler is not limited to a specific value, but is preferably in the range of about 0.01 to 90 μm, and more preferably in the range of about 0.1 to 40 μm. If the average particle size exceeds the upper limit value, there is a fear that appearance and resolution of the spacer formation layer 12 are lowered. On the other hand, if the average particle size is less than the above lower limit value, there is a fear that the transparent substrate 102 cannot be reliably bonded to the spacer 104 even by the thermal bonding.

In this regard, it is to be noted that the average particle size is measured using, for example, a particle size distribution measurement apparatus of a laser diffraction type (“SALD-7000” produced by Shimadzu Corporation).

Further, in the case where the porous filler is used as the inorganic filler, an average hole size of the porous filler is preferably in the range of about 0.1 to 5 nm, and more preferably in the range of about 0.3 to 1 nm.

The resin composition constituting the spacer formation layer 12 also can contain an additive agent such as an ultraviolet absorber, a plastic resin, a leveling agent, a defoaming agent or a coupling agent in addition to the above components insofar as the purpose of the present invention is not spoiled.

By constituting the spacer formation layer from the resin composition described above, it is possible to more appropriately adjust visible light transmission through the spacer formation layer 12. Therefore, when a mask 20 is placed as described below, an alignment mark formed on the semiconductor wafer 101′ can be well visually confirmed. This makes it possible to position the mask 20 in a high accuracy, to thereby more effectively prevent the exposure from becoming insufficiency during the exposing step. As a result, it is possible to provide a semiconductor device 100 having higher reliability.

Further, it is also possible to more appropriately adjust exposure light transmission through the spacer formation layer 12, to thereby more effectively prevent the exposure from becoming insufficiency during the exposing step. As a result, it is possible to provide a semiconductor device 100 having higher reliability.

A1-2

On the other hand, as shown in FIG. 4(b), the plurality of light receiving portions 103 are formed onto the one surface of the semiconductor wafer 101′. Specifically, the plurality of light receiving elements and the plurality of microlens arrays are formed onto the one surface of the semiconductor wafer 101′ in this order.

A1-3

Next, as shown in FIG. 4(c), the spacer formation layer 12 of the spacer formation film 1 described above is attached to the one surface of the semiconductor wafer 101′ from a side of the one surface thereof (that is, laminating processing is carried out).

<<A2>> Step of Forming Spacer 104′ by Selectively Removing Spacer Formation Layer 12

A2-1

Next, as shown in FIG. 4(d), the exposure treatment is carried out by irradiating the spacer formation layer 12 with an exposure light (ultraviolet ray) (that is, this process is referred to as an exposure process).

At this time, as shown in FIG. 4(d), the spacer formation layer 12 is irradiated with the exposure light through a mask 20 having a light passing portion 201 with a top view shape corresponding to a top view shape of the spacer 104′.

The light passing portion 201 has light transparency. Therefore, the spacer formation layer 12 is irradiated with the exposure light passed through the light passing portion 201. In this way, the spacer formation layer 12 is selectively exposed so that a region thereof which is irradiated with the exposure light is photo-cured.

Further, as shown in FIG. 4(d), the exposure treatment with respect to the spacer formation layer 12 is carried out in a state that the support base 11 is attached to the spacer formation layer 12. Therefore, the spacer formation layer 12 is irradiated with the exposure light passed through the support base 11.

For this reason, the support base 11 can function as a protective layer of the spacer formation layer 12 during the exposure treatment, which makes it possible to prevent adhesion of foreign substances such as dust to the surface of the spacer formation layer 12 effectively. Further, even in the case where the foreign substances adhere to the support base 11, they can be easily removed.

Furthermore, even when the mask 20 is placed as described above, it is possible to prevent the mask 20 from adhering to the spacer formation layer 12, while making a distance between the mask 20 and the spacer formation layer 12 smaller. As a result, it is possible to prevent an image to be formed from the exposure light, with which the spacer formation layer 12 is irradiated, from becoming dim.

In this case, a border between an exposed region and a non-exposed region can become sharp (clear). As a result, it is possible to form the spacer 104′ at a sufficient dimensional accuracy, to thereby obtain each air-gap portion 105 so as to have close designed shape and size. This makes it possible to improve reliability of a semiconductor device 100.

Further, in this embodiment, as shown in FIG. 4(d), alignment marks 1011 are provided on the semiconductor wafer 101′ near an outer edge portion thereof.

likewise, as shown in FIG. 4(d), alignment marks 202 for positioning are provided on the mask 20.

By aligning the alignment marks 1011 provided on the semiconductor wafer 101′ with the alignment marks 202 provided on the mask 20 in the exposure step, the mask 20 is positioned with respect to the semiconductor wafer 101′. In this way, by carrying out the positioning of the mask 20 using the alignment marks 1011 and the alignment marks 202, the spacer 104′ can be formed in a high positional accuracy. As a result, it is possible to further improve the reliability of the semiconductor device 100.

At this time, especially, there is the predetermined relationship between the thickness and the absorbance index of the support base 11 and the thickness and the absorbance index of the spacer formation layer 12.

Specifically, in the case where the absorbance index of the support base 11 within wavelength band of visible light is defined as α_{V1} (1/μm) and the absorbance index of the spacer formation layer 12 within the wavelength band of the visible light is defined as α_{V2} (1/μm), each of the following relational expressions <1> to <4> is satisfied.

α_{V1}×t₁+α_{V2}×t₂≦−log₁₀(0.2) <1>

5≦t₁≦200 <2>

5≦t₂≦400 <3>

10≦t₁+t₂≦405 <4>

By satisfying the above relational expressions <1> to <4>, it is possible to well visually confirm a surface of the semiconductor wafer 101′ which is located at a side of the spacer formation layer 12 through the support base 11 and the spacer formation layer 12. This makes it possible to well visually confirm the alignment marks 1011 formed on the semiconductor wafer 101′ when the mask 20 is placed. Therefore, the positioning of the mask 20 can be reliably carried out (that is, ease of mask alignment can be improved). As a result, it is possible to form a spacer 104 having an excellent dimensional accuracy.

In this regard, in the present specification, the absorbance index is a constant indicating a degree that a medium absorbs light when the light is entered into the medium. Such a constant is a value defined by conditions of a medium to be objected such as a material thereof and a density thereof, and a wavelength of light to be used.

Hereinbelow, description will be made on the above relational expressions <1> to <4> in detail.

As show in FIG. 6, when the spacer formation layer 12 is irradiated with visible light through the support base 11, in the case where an amount of the visible light incidence into the support base 11 (that is, a radiant exitance) is defined as I_{V0}, an amount of the visible light passed through the support base 11 (that is, an amount of the visible light incidence into the spacer formation layer 12) is defined as I_{V1}, an amount of the visible light passed through the spacer formation layer 12 is defined as I_{V2}, visible light transmission through the support base 11 in a thickness direction thereof is defined as T_{V1}, visible light transmission through the spacer formation layer 12 in a thickness direction thereof is defined as T_{V2} and visible light transmission through the entire of the spacer formation film 1 (that is, the support base 11 and the spacer formation layer 12) in a thickness direction thereof is defined as T_{V}, the following relational expressions <A> to <C> can be drawn.

T_{V1}=I_{V1}/I_{V0}=10^{-αV1·t1} <A>

T_{V2}=I_{V2}/I_{V1}=10^{-αV2·t2} <B>

T_{V}=T_{V1}·T_{V2}=I_{V2}/I_{V0}=10^{-<αV1·t1+αV2·t2>} <C>

In this regard, for convenience of the description, without regard to light absorption, light distribution and the like between the support base 11 and the spacer formation layer 12, a radiant exitance of the visible light passed through the support base 11 is assumed to be equal to a radiant exitance of the visible light incidence into the spacer formation layer 12.

In the case where the positioning of the mask 20 is carried out using the alignment marks 1011 and the alignment marks 202 as described above, in order to improve an accuracy of the positioning thereof, it is required that the alignment marks 1011 can be well visually confirmed through the support base 11 and the spacer formation layer 12. Therefore, the transmissions T_{V}, T_{V1} and T_{V2} have to make large.

In order that the transmission T_{V} makes large, (α_{V1}×t₁+α_{V2}×t₂) has to make small as understood from the relational expression <C>.

The following relational expression <D> can be drawn from the above relational expression <C>.

α_{V1}×t₁+α_{V2}×t₂=−log₁₀(T_{V}) <D>

Here, there is a relationship between −log₁₀(T_{V}) and T_{V} as shown in FIG. 7.

As understood from FIG. 7, in the case where −log₁₀(T_{V}) becomes about 0.7 (=−log₁₀(0.2)) or less, the transmission T_{V} drastically increases. In other words, in the case where −log₁₀(T_{V}) exceeds about 0.7, the transmission T_{V} drastically decreases.

Therefore, by setting (α_{V1}×t₁+α_{V2}×t₂) to a value of −log₁₀(0.2) or less, that is, by satisfying the above relational expression <1>, it is possible to make the transmission T_{V} large (high).

The present inventors have further examined appropriate values of the thicknesses t1, t2 on the assumption that the above relational expression <1> is satisfied. As a result, the present inventors have found the appropriate values, to thereby obtain the above relational expressions <2> to <4>.

By forming the support base 11 and the spacer formation layer 12 so as to satisfy such relational expressions <1> to <4>, the ease of mask alignment can be improved as described above.

On the other hand, in the case where (α_{V1}×t₁+α_{V2}×t₂) is set to a value of more than −log₁₀(0.2), it is impossible to visually confirm a lower surface of the spacer formation layer 12 sufficiently. This causes remarkable lowering of the ease of mask alignment.

Further, if an average thickness t₁ of the support base 11 is less than 5 μm, the support base 11 cannot exhibit the function of supporting the spacer formation layer 12. On the other hand, if the average thickness t₁ of the support base 11 exceeds 200 μm, it becomes difficult to select a material satisfying the above relational expression <1> as a constituent material of the support base 11. Further, it also becomes difficult to handle the spacer formation film 1.

Furthermore, if an average thickness t₂ of the spacer formation layer 12 is less than 5 μm, the spacer 104 cannot form (define) an air-gap portion 105 having a necessary size. On the other hand, if the average thickness t₂ of the spacer formation layer 12 exceeds 400 μm, it becomes difficult to select a material satisfying the above relational expression <1> as the constituent material of the spacer formation layer 12.

Moreover, if an average thickness (t₁+t₂) of the spacer formation film 1 is less than 10 μm, the support base 11 cannot exhibit the function of supporting the spacer formation layer 12 and/or cannot form (define) an air-gap portion 105 having a necessary size. On the other hand, if the average thickness (t₁+t₂) of the spacer formation film 1 exceeds 405 μm, it becomes difficult to select a material satisfying the above relational expression <1> as the constituent materials of the support base 11 and the spacer formation layer 12. Further, it also becomes difficult to handle the spacer formation film 1.

Further, it is preferred that each of the following relational expressions <5> to <7> is satisfied.

I_{V1}/I_{V0}≧0.2 <5>

I_{V2}/I_{V1}≧0.2 <6>

I_{V2}/I_{V0}≧0.2 <7>

By satisfying the relational expressions <5> to <7>, it is possible to more reliably carry out the accurate positioning of the mask 20 (that is, it is possible to improve the ease of mask alignment).

Especially, from the viewpoint of improving the ease of mask alignment, it is more preferred that each of the following relational expressions is satisfied.

I_{V1}/I_{V0}≧0.4

I_{V2}/I_{V1}≧0.4

I_{V2}/I_{V0}≧0.4

In this regard, “I_{V1}/I_{V0}” is equal to the visible light transmission through the support base 11 in the thickness direction thereof “T_{V1}”, “I_{V2}/I_{V1}” is equal to the visible light transmission through the spacer formation layer 12 in the thickness direction thereof “T_{V2}” and “I_{V2}/I_{V0}” is equal to the visible light transmission through the spacer formation film 1 in the thickness direction thereof “T_{V}”.

Further, in the case where an absorbance index of the support base 11 within wavelength band of an exposure light used in the exposure treatment during the exposure step <<A2>> is defined as α_{E1} and an absorbance index of the spacer formation layer 12 within the wavelength band of the exposure light is defined as α_{E2}, each of the following relational expressions <8> to <11> is satisfied.

α_{E1}×t₁+α_{E2}×t₂≦−log₁₀(0.2) <8>

5≦t₁≦100 <9>

5≦t₂≦350 <10>

10≦t₁+t₂≦400 <11>

In the case where the support base 11 and the spacer formation layer 12 are formed so as to satisfy the above relational expressions <8> to <11>, it is possible for the entire of the spacer formation layer 12 along a thickness direction thereof to be reliably irradiated with the exposure light in the exposure step, while the spacer formation film 1 exhibits the above mentioned effect of improving the ease of mask alignment.

Therefore, it is possible to prevent a dissolving phenomenon of a portion of the spacer formation layer 12 near a surface thereof located at the side of the semiconductor wafer 101′ (that is, a undercut) from occurring in the development, which would be caused by blocking sufficient arrival of the exposure light to the portion of the spacer formation layer 12 during the exposure step. As a result, it is possible to form a spacer 104′ having an excellent dimensional accuracy.

Further, since the spacer 104′ and the semiconductor wafer 101′ are bonded together reliably, it is possible to obtain a semiconductor wafer bonding product 1000 and a semiconductor device each having superior reliability.

Hereinbelow, description will be made on the above relational expressions <8> to <11> in detail.

As shown in FIG. 6, when the spacer formation layer 12 is irradiated with an exposure light through the support base 11, in the case where an amount of the exposure light incidence into the support base 11 (that is, a radiant exitance) is defined as I_{E0}, an amount of the exposure light passed through the support base 11 (that is, an amount of the exposure light incidence into the spacer formation layer 12) is defined as I_{E1}, an amount of the exposure light passed through the spacer formation layer 12 is defined as I_{E2}, exposure light transmission through the support base 11 in a thickness direction thereof is defined as T_{E1}, exposure light transmission through the spacer formation layer in a thickness direction thereof is defined as T_{E2} and exposure light transmission through the entire of the spacer formation film 1 (that is, the support base 11 and the spacer formation layer 12) in a thickness direction thereof is defined as T_{E}, the following relational expressions <A1> to <C1> can be drawn.

T_{E1}=I_{E1}/I_{E0}=10^{-αE1·t1} <A1>

T_{E2}=I_{E2}/I_{E1}=10^{-αE2·t2} <B1>

T_{E}=T_{E1}·T_{E2}=I_{E2}/I_{E0}=10^{-<αE1·t1+αE2·t2>} <C1>

In this regard, for convenience of the description, without regard to light absorption, light distribution and the like between the support base 11 and the spacer formation layer 12, a radiant exitance of the exposure light passed through the support base 11 is assumed to be equal to a radiant exitance of the exposure light incidence into the spacer formation layer 12.

In order to effectively carry out the exposure step, the transmissions T_{E}, T_{E1} and T_{E2} have to make large.

In order that the transmission T_{E} makes large, (α_{E1}×t₁+α_{E2}×t₂) has to make small as understood from the relational expression <C1>.

The following relational expression <D1> can be drawn from the above relational expression <C1>.

α_{E1}×t₁+α_{E2}×t₂=−log₁₀(T_{E}) <D1>

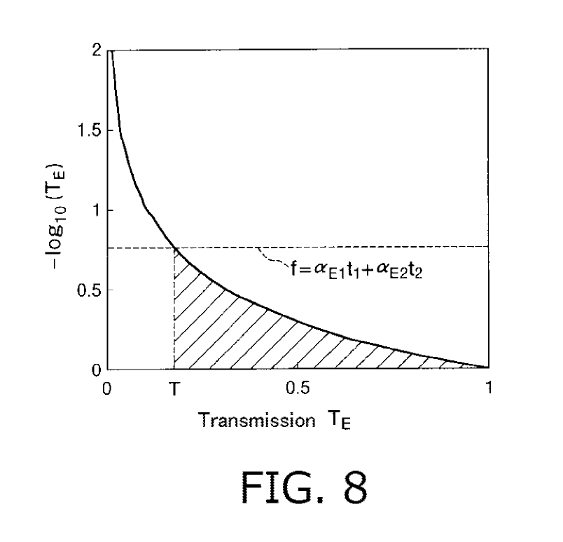

Here, there is a relationship between −log₁₀ (T_{E}) and T_{E} as shown in FIG. 8.

As understood from the FIG. 8, in the case where −log₁₀(T_{E}) becomes about 0.7 (=−log₁₀(0.2)) or less, the transmission T_{E} drastically increases. In other words, in the case where −log₁₀(T_{E}) exceeds about 0.7, the transmission T_{E} drastically decreases.

Therefore, by setting (α_{E1}×t₁+α_{E2}×t₂) to a value of −log₁₀(0.2) or less, that is, by satisfying the above relational expression <8>, it is possible to make the transmission T_{E} large.

The present inventors have further examined appropriate values of the thicknesses t1, t2 on the assumption that the above relational expression <8> is satisfied. As a result, the present inventors have found the appropriate values, to thereby obtain the above relational expressions <9> to <11>.

By forming the support base 11 and the spacer formation layer 12 so as to satisfy such relational expressions <8> to <11>, it is possible to form a spacer 104′ having an excellent dimensional accuracy as described above.

Further, since the spacer 104′ and the semiconductor wafer 101′ are bonded together reliably, it is possible to obtain a semiconductor wafer bonding product 1000 and a semiconductor device 100 each having superior reliability.

On the other hand, in the case where (α_{E1}×t₁+α_{E2}×t₂) is set to a value of more than −log₁₀(0.2), it is impossible for the lower surface of the spacer formation layer 12 to be sufficiently irradiated with the exposure light depending on conditions of the exposure step, the constituent materials of the support base 11 and the spacer formation layer 12 or the like. This may cause occurrence of the undercut.

Further, if the average thickness t₁ of the support base 11 exceeds 100 μm, it becomes difficult to select a material satisfying the above relational expression <8> as the constituent material of the support base 11.

Furthermore, if the average thickness t₂ of the spacer formation layer 12 exceeds 350 μm, it becomes difficult to select a material satisfying the above relational expression <8> as the constituent material of the spacer formation layer 12.

Moreover, if the average thickness (t₁+t₂) of the spacer formation film 1 exceeds 400 μm, it becomes difficult to select a material satisfying the above relational expression <8> as the constituent materials of the support base 11 and the spacer formation layer 12.

When the relational expressions <8> to <11> are satisfied, in the case where an amount of the exposure light incidence into the support base 11 is defined as I_{E0}, an amount of the exposure light passed through the support base 11 is defined as I_{E1} and an amount of the exposure light further passed through the spacer formation layer 12 is defined as I_{E2}, each of the following relational expressions <12> to <14> is satisfied.

I_{E1}/I_{E0}≧0.2 <12>

0.1≦I_{E2}/I_{E1}≦0.9 <13>

0.1≦I_{E2}/I_{E0}≦0.9 <14>

By satisfying the relational expressions <12> to <14>, it is possible for the entire of the spacer formation layer 12 along the thickness direction thereof to be more reliably irradiated with the exposure light. This makes it possible to prevent the problem on the above described undercut from being generated.

Especially, from the viewpoint of preventing the problem on the above described undercut from being generated, it is more preferred that the following relational expression is satisfied.

I_{E1}/I_{E0}≧0.4

In this regard, “I_{E1}/I_{E0}” is equal to the exposure light transmission through the support base 11 in the thickness direction thereof “T_{E1}”, “I_{E2}/I_{E1}” is equal to the exposure light transmission through the spacer formation layer 12 in the thickness direction thereof “T_{E2}” and “I_{E2}/I_{E0}” is equal to the exposure light transmission through the spacer formation film 1 in the thickness direction thereof “T_{E}”.

Further, a distance between the support base 11 and the mask 20 is preferably in the range of 0 to 2,000 μm, and more preferably in the range of 0 to 1,000 μm. This makes it possible to more clearly form the image to be formed from the exposure light, with which the spacer formation layer 12 is irradiated through the mask 20, to thereby form the spacer 104 at a sufficient dimensional accuracy.

Especially, it is preferred that the exposure treatment is carried out in a state that the mask 20 makes contact with the support base 11. This makes it possible to keep a distance between the spacer formation layer 12 and the mask 20 stably and constantly in a whole region thereof. As a result, it is possible to uniformly expose a region of the spacer formation layer 12 to be exposed, to thereby more effectively form a spacer 104′ having an excellent dimensional accuracy.

In the case where the exposure is carried out in such a state that the mask 20 makes contact with the support base 11, by appropriately selecting the thickness of the support base 11, it is possible to set the distance between the support base 11 and the mask freely and reliably. Further, by adjusting the thickness of the support base 11 to a small size, it is possible to make the distance between the spacer formation layer 12 and the mask 20 smaller. This makes it possible to prevent the image to be formed from the exposure light, with which the spacer formation layer 12 is irradiated, from becoming dim.

In this regard, in the present specification, the exposure light transmission through each of the support base 11 and the spacer formation layer 12 in the thickness direction thereof means a ratio of a peak wavelength (e.g., 365 nm) of the exposure light passed through each of the support base 11 and the spacer formation layer 12 in the thickness direction thereof.

On the other hand, the visible light transmission through each of the support base 11 and the spacer formation layer 12 in the thickness direction thereof means a ratio of a peak wavelength of a light having a wavelength of 600 nm passed through each of the support base 11 and the spacer formation layer 12 in the thickness direction thereof.

Further, the light transmission through each of the support base 11 and the spacer formation layer 12 in the thickness direction thereof can be measured using, for example, a transmission measuring apparatus (“UV-160A” produced by Shimadzu Corporation).

In this regard, it is to be noted that after the exposure as described above, the spacer formation layer 12 may be subjected to a baking (heating) treatment at a temperature of about 40 to 80° C. (this process is referred to as a post exposure baking process (PEB process)), if needed. By subjecting the spacer formation layer 12 to such a baking treatment, it is possible to further improve adhesion between the region of the spacer formation layer 12 photo-cured in the exposure step (that is, the spacer 104′) and the semiconductor wafer 101′. This makes it possible to effectively prevent the photo-cured region of the spacer formation layer 12 from being involuntarily peeled off (delaminated) from the semiconductor wafer 101′.

A heat temperature in the baking treatment is preferably in the range of about 50 to 70° C. This makes it possible to more effectively prevent the photo-cured region of the spacer formation layer 12 from being involuntarily peeled off (delaminated) from the semiconductor wafer 101′ during the developing process described below.

A2-2

Next, as shown in FIG. 4(e), the support base 11 is removed (this process is referred to as a support base removing process). Namely, the support base 11 is peeled off from the spacer formation layer 12.

A2-3

Next, as shown in FIG. 4(f), the non-cured region of the spacer formation layer 12 is removed using a developer (this process is referred to as a developing process). By doing so, the photo-cured region of the spacer formation layer 12 is remained, to thereby form the spacer 104′ and the air-gap portions 105′.

At this time, in the case where the spacer formation layer 12 contains the above mentioned alkali soluble resin, an alkali aqueous solution can be used as the developer.

<<A3>> Step of Bonding Transparent Substrate 102′ to Surface of Spacer 104′ Opposite to Semiconductor Wafer 101′

Next, as shown in FIG. 4(g), the transparent substrate 102′ is bonded to an upper surface of the formed spacer 104′ (this step is referred to as a bonding step). In this way, it is possible to obtain a semiconductor wafer bonding product 1000 (semiconductor wafer bonding product of the present invention) in which the semiconductor wafer 101′ and the transparent substrate 102′ are bonded together through the spacer 104′.

The bonding of the transparent substrate 102′ to the spacer 104′ can be carried out by, for example, attaching the transparent substrate 102′ to the upper surface of the formed spacer 104′, and then being subjected to thermal bonding.

The thermal bonding is preferably carried out within a temperature range of 80 to 180° C. This makes it possible for the spacer 104′ and the transparent substrate 102′ to be bonded together by the thermal bonding, while suppressing the pressure to be applied during the thermal bonding. Therefore, involuntary deformation of the spacer 104 to be formed can be prevented, to thereby improve a dimensional accuracy thereof.

<<A4>> Step of Subjecting Lower Surface of Semiconductor Wafer 101′ to Predetermined Processing or Treatment

A4-1

Next, as shown in FIG. 5(h), ground is a surface (lower surface) 111 of the semiconductor wafer 101′ opposite to the transparent substrate 102′ (this process is referred to as a back grinding process).

This surface 111 of the semiconductor wafer 101′ can be ground using, for example, a grinding machine (grinder).

By grinding such a surface 111, a thickness of the semiconductor wafer 101′ is generally set to about 100 to 600 μm depending on an electronic device in which the semiconductor device 100 is used. In the case where the semiconductor device 100 is used in an electronic device having a smaller size, the thickness of the semiconductor wafer 101′ is set to about 50 μm.

A4-2

Next, as shown in FIG. 5(i), the solder bumps 106 are formed onto the surface 111 of the semiconductor wafer 101′.

At this time, a circuit (wiring) is also formed onto the surface 111 of the semiconductor wafer 101′ in addition to the solder bumps 106, but is not shown in the drawings.

[B] Step of Dicing Semiconductor Wafer Bonding Product 1000

Next, the semiconductor wafer bonding product 1000 is diced, to thereby obtain the plurality of semiconductor devices 100 (this step is referred to as a dicing step).

At this time, the semiconductor wafer bonding product 1000 is diced so as to correspond to each individual circuit formed on the semiconductor wafer 101′, that is, each air-gap portion 105.

For example, the dicing of the semiconductor wafer bonding product 1000 is carried out by, as shown in FIG. 5(j), forming grooves 21 coming down to an interface between the spacer 104′ and the semiconductor wafer 101′ from a side of the transparent substrate 102′ using a dicing saw along a grid of the spacer 104′, and then also forming grooves 22 into the semiconductor wafer 101′.

In this regard, the dicing of the semiconductor wafer bonding product 1000 may be carried out by cutting the transparent substrate 102′, the spacer 104′ and the semiconductor wafer 101′ at once. Further, the grooves also may be formed from the side of the semiconductor wafer 101′.

Through the above steps, the semiconductor device 100 can be manufactured.

In this way, by dicing the semiconductor wafer bonding product 1000 to thereby obtain the plurality of semiconductor devices 100 at the same time, it is possible to mass-produce the semiconductor devices 100, and thus to improve productive efficiency thereof.

In this regard, for example, by mounting the semiconductor device 100 on a substrate provided with a circuit (patterned wiring), the circuit formed on the substrate is electrically connected to the circuit formed on the lower surface of the base substrate 101 via the solder bumps 106.

Further, the semiconductor device 100 mounted on the support substrate as described above can be widely used in electronics such as a cellular telephone, a digital camera, a video camera and a miniature camera.

In this regard, in the above description, the spacer formation layer 12 formed on the semiconductor wafer 101′ is exposed and developed to obtain the spacer 104′, and then the transparent substrate 102′ is bonded to the spacer 104′, but this order may be changed. The spacer formation layer 12 formed on the transparent substrate 102′ may be exposed and developed to obtain the spacer 104′, and then the semiconductor wafer 101′ may be bonded to the spacer 104′.

In this case, it is preferred that the positioning of the mask 20 is carried out using alignment marks provided on the transparent substrate 102′ and alignment marks provided on the mask 20 in the exposure process (exposure step). This makes it possible to form the spacer 104′ in a high positional accuracy, to thereby further improve the reliability of the semiconductor device 100 to be manufactured.

While the present invention has been described hereinabove with reference to the preferred embodiments, the present invention is not limited thereto.

For example, in the method of manufacturing a semiconductor wafer bonding product according to the present invention, one or more steps (processes) may be added for arbitrary purposes. For example, between the laminating process and the exposure process, a post laminate baking process (PLB process), in which the spacer formation layer is subjected to a baking (heating) treatment, may be provided.

Further, in the description of the above embodiments, the exposure is carried out just once, but may be, for example, more than once.

Furthermore, each component constituting the spacer formation film, the semiconductor wafer bonding product and the semiconductor device is substituted for an arbitrary component having the same function as it, or arbitrary structures also may be added thereto.

### EXAMPLES

Hereinafter, description will be made on concrete examples of the present invention. In this regard, it is to be noted that the present invention is not limited thereto.

### [1] Manufacture of Semiconductor Wafer Bonding Product

### Example 1

### 1. Synthesis of Alkali Soluble Resin (Methacryloyl-Modified Novolac-Type Bisphenol a Resin)

500 g of a MEK (methyl ethyl ketone) solution containing a novolac-type bisphenol A resin (“Phenolite LF-4871” produced by DIC corporation) with a solid content of 60% was added into a 2 L flask. Thereafter, 1.5 g of tributylamine as a catalyst and 0.15 g of hydroquinone as a polymerization inhibitor were added into the flask, and then they were heated at a temperature of 100° C. Next, 180.9 g of glycidyl methacrylate was further added into the flask in drop by drop for 30 minutes, and then they were reacted with each other by being stirred for 5 hours at 100° C., to thereby obtain a methacryloyl-modified novolac-type bisphenol A resin “MPN001” (methacryloyl modified ratio: 50%) with a solid content of 74%.

### 2. Preparation of Resin Varnish Containing Resin Composition Constituting Spacer Formation Layer

15 wt % of trimethylol propane trimethacrylate (“LIGHT-ESTER TMP” produced by KYOEISHA CHEMICAL Co., LTD.) and 5 wt % of an epoxy vinyl ester resin (“EPOXY-ESTER 3002M” produced by KYOEISHA CHEMICAL Co., LTD) as a photo polymerizable resin; 5 wt % of bisphenol A novolac-type epoxy resin (“Epiclon N-865” produced by DIC Corporation, 10 wt % of a bisphenol A-type epoxy resin (“YL 6810” produced by Japan Epoxy Resins Co., Ltd) and 5 wt % of a silicone epoxy resin (“BY 16-115” produced by Dow Corning Toray Co., Ltd) as an epoxy resin which was a thermosetting resin; 3 wt % of a phenol novolac resin (“PR 53647” produced by Sumitomo Bakelite Co., Ltd.); 54.8 wt % of the above MPN001 (solid content) as an alkali soluble resin; 2 wt % of a photo initiator (“IRGACURE 651” produced by Ciba Specialty Chemicals); and 0.2 wt % of an ultraviolet absorber (“Viosorb 550” produced by KYODO CHEMICAL COMPANY LIMITED) were weighed, and stirred at a rotation speed of 3,000 rpm for 1 hour using a disperser, to prepare a resin varnish.

### 3. Production of Spacer Formation Film

First, prepared was a polyester film having a thickness of 5 μm (“MRX 50” produced by Mitsubishi Plastics, Inc.) as a support base. Visible light (600 nm) transmission through the support base in a thickness direction thereof “T_{V1}” was 98.7%. An absorbance index of the support base with respect to visible light (600 nm) in a thickness direction thereof “α_{V1}” was 0.0011 (1/μm). Exposure light (365 nm) transmission through the support base in a thickness direction thereof “T_{E1}” was 97.7%. Further, an absorbance index of the support base with respect to an exposure light (365 nm) in a thickness direction thereof “α_{E1}” was 0.002 (1/μm).

Next, the above prepared resin varnish was applied onto the support base using a konma coater “model number: MGF No. 194001 type 3-293” produced by YASUI SEIKI) to form a coating film constituted from the resin varnish. Thereafter, the formed coating film was dried at 80° C. for 20 minutes to form a spacer formation layer. In this way, the spacer formation film was obtained. In the obtained spacer formation film, an average thickness of the spacer formation layer was 5 μm.

Visible light (600 nm) transmission through the formed spacer formation layer in a thickness direction thereof “T_{V2}” was 98.8%. An absorbance index of the spacer formation layer with respect to visible light (600 nm) in a thickness direction thereof “α_{V2}” was 0.0002 (1/μm). Exposure light (365 nm) transmission through the formed spacer formation layer in a thickness direction thereof “T_{E2}” was 89.5%. Further, an absorbance index of the spacer formation layer with respect to an exposure light (365 nm) in a thickness direction thereof “α_{E2}” was 0.0096 (1/μm).

### 4. Manufacture of Bonding Product

First, prepared was a semiconductor wafer having a substantially circular shape and a diameter of 8 inches (Si wafer, diameter of 20.3 cm and thickness of 725 μm). In this regard, it is to be noted that 2 alignment marks were formed on the semiconductor wafer so as to be symmetrical with respect to a point corresponding to a central axis of the semiconductor wafer at an inside position of 5 mm from the edge of the semiconductor wafer.

Next, the above produced spacer formation film was laminated on the semiconductor wafer using a roll laminater under the conditions in which a roll temperature was 60° C., a roll speed was 0.3 m/min and a syringe pressure of 2.0 kgf/cm², to thereby obtain the semiconductor wafer with the spacer formation film.

Next, prepared was a mask provided with 2 alignment marks for positioning with respect to the semiconductor wafer and a light passing portion having the same shape as a planar shape of a spacer to be formed. Thereafter, the mask was placed so as to face the spacer formation film, while aligning the alignment marks of the mask with the alignment marks of the semiconductor wafer. At this time, a distance between the mask and the support base was set to 0 mm.

Next, the semiconductor wafer with the spacer formation film was selectively irradiated with an ultraviolet ray (wavelength of 365 nm and accumulated light intensity of 700 mJ/cm²) from a side of the spacer formation film so that the spacer formation layer was exposed in grid-like fashion, and then the support base was removed therefrom. In this regard, it is to be noted that when exposing the spacer formation layer, 50% of the spacer formation layer is exposed in a planar view thereof so that a width of a region to be exposed in grid-like fashion becomes 0.6 mm.

Next, the exposed spacer formation layer was developed using 2.38 wt % of tetramethyl ammonium hydroxide (TMAH) aqueous solution as a developer (alkali solution) under the conditions in which a developer pressure was 0.2 MPa and a developing time was 90 seconds. In this way, formed was a spacer composed of ribs each having a width of 0.6 mm onto the semiconductor wafer.

Next, prepared was a transparent substrate (quartz glass substrate, diameter of 20.3 mm and thickness of 725 μm). This transparent substrate was bonded to the semiconductor wafer, on which the spacer had been formed, by compression bonding using a substrate bonder (“SB8e” produced by Suss Microtec k.k.). In this way, manufactured was a semiconductor wafer bonding product in which the transparent substrate was bonded to the semiconductor wafer through the spacer.

### Examples 2 to 9 and Comparative Examples 1 and 2

Each of semiconductor wafer bonding products was manufactured in the same manner as Example 1, except that the absorbance index “α_{E1}” and the thickness “t₁” of the support base and the absorbance index “α_{E2}” and the thickness “t₂” of the spacer formation layer were changed as shown in Table 1.

Here, in Comparative Example 2, a polyimide film (“upilex 25SGA” produced by UBE INDUSTRIES, LTD.) was used as the support base. Further, in Examples 4 to 9 and Comparative Examples 1 and 2, as shown in Table 2, the absorbance indexes “α_{V2}” and “α_{E2}” of the spacer formation layer were adjusted by changing the compounding ratio of the resin varnish used for forming the spacer formation layer.

In this regard, in Table 2, indicated are the methacryloyl-modified novolac-type bisphenol A resin as “MPN”, the trimethylol propane trimethacrylate as “TMP”, the epoxy vinyl ester resin as “3002M”, the bisphenol A novolac-type epoxy resin as “N865”, the bisphenol A-type epoxy resin as “YL”, the silicone epoxy resin as “BY16”, the phenol novolac resin as “PR” and triethylene glycol dimethacrylate (“NKESTER3G” produced by Shin-Nakamura Chemical CO., Ltd.) as “3G”, respectively.

Further, in Examples 7 to 9 and Comparative Example 2, but not shown in Table 2, 30 wt % of a silica filler having an average particle size of 0.125 μm and a maximal particle size of 0.35 μm (“NS-3N” produced by Tokuyama Corporation) was added.

TABLE 1

| | Support base | | | | | Spacer formation layer | | | | | Spacer formation film | | | | Evaluation | |
|---|---|---|---|---|---|---|---|---|---|---|---|---|---|---|---|---|
| | Light | | Absorbance | | | Light | | Absorbance | | | | | Light | | Ease | |
| | transmission | | index | | Average | transmission | | index | | Average | | | transmission | | of | |
| | [%] | | [1/μm] | | thickness | [%] | | [1/μm] | | thickness | −log₁₀ | −log₁₀ | [%] | | mask | Under- |
| | T_{V1} | T_{E1} | α_{V1} | α_{E1} | t₁ [μm] | T_{V2} | T_{E2} | α_{V2} | α_{E2} | t₂ [μm] | (T_{V}) | (T_{E}) | T_{V} | T_{E} | alignment | cut |
| Ex. 1 | 98.7 | 97.7 | 0.0011 | 0.002 | 5 | 99.8 | 89.5 | 0.0002 | 0.0096 | 5 | 0.01 | 0.06 | 98.5 | 87.5 | A | A |
| Ex. 2 | 90.8 | 83.9 | 0.0011 | 0.002 | 38 | 97.7 | 33.1 | 0.0002 | 0.0096 | 50 | 0.05 | 0.56 | 88.8 | 27.8 | A | B |
| Ex. 3 | 77.6 | 63.1 | 0.0011 | 0.002 | 100 | 97.7 | 33.1 | 0.0002 | 0.0096 | 50 | 0.12 | 0.68 | 75.9 | 20.9 | A | B |
| Ex. 4 | 60.3 | 39.8 | 0.0011 | 0.002 | 200 | 93.3 | 55.6 | 0.0002 | 0.0017 | 150 | 0.25 | 0.66 | 56.2 | 22.1 | A | B |
| Ex. 5 | 90.8 | 83.9 | 0.0011 | 0.002 | 38 | 85.1 | 25.4 | 0.0002 | 0.0017 | 350 | 0.11 | 0.67 | 77.3 | 21.3 | A | B |
| Ex. 6 | 98.7 | 97.7 | 0.0011 | 0.002 | 5 | 83.2 | 20.9 | 0.0002 | 0.0017 | 400 | 0.09 | 0.69 | 82.1 | 20.4 | A | B |
| Ex. 7 | 90.8 | 83.9 | 0.0011 | 0.002 | 38 | 94.2 | 65.3 | 0.0052 | 0.0370 | 5 | 0.07 | 0.26 | 85.5 | 54.8 | A | A |
| Ex. 8 | 93.9 | 89.1 | 0.0011 | 0.002 | 25 | 83.6 | 27.9 | 0.0052 | 0.0370 | 15 | 0.11 | 0.61 | 78.4 | 24.8 | B | B |
| Ex. 9 | 90.8 | 83.9 | 0.0011 | 0.002 | 38 | 55.0 | 1.41 | 0.0052 | 0.0370 | 50 | 0.30 | 1.93 | 49.9 | 1.2 | A | D |
| Com. | 93.9 | 89.1 | 0.0011 | 0.002 | 25 | 14.1 | 5.31 | 0.0340 | 0.0510 | 25 | 0.88 | 1.33 | 13.3 | 4.7 | D | D |
| Ex. 1 | | | | | | | | | | | | | | | | |
| Com. | 31.6 | 0.00 | 0.0100 | 0.1 | 50 | 55.0 | 1.41 | 0.0052 | 0.0370 | 50 | 0.76 | 6.85 | 17.4 | 0.0 | D | D |
| Ex. 2 | | | | | | | | | | | | | | | | |

TABLE 2

| | Spacer formation film | | | | | | | | | | | | | | | |
|---|---|---|---|---|---|---|---|---|---|---|---|---|---|---|---|---|
| | Constituent material of resin composition constituting spacer formation layer | | | | | | | | | | | | | | | |
| | | | | | | | | | | | | | | | Photo | |
| | Alkali | | | | | | | | | | | | | | Polymeri- | |
| | Soluble | | | | | | | | | | | | | | zation | Ultraviolet |
| | resin | | Photo polymerizable resin | | | | Thermosetting resin | | | | | | | | initiator | absorber |
| | | Amount | | Amount | | Amount | | Amount | | Amount | | Amount | | Amount | Amount | Amount |
| | Kind | [wt %] | Kind | [wt %] | Kind | [wt %] | Kind | [wt %] | Kind | [wt %] | kind | [wt %] | kind | [wt %] | [wt %] | [wt %] |
| Ex. 1 | MPN | 54.8 | TMP | 15 | 3002M | 5 | N865 | 5 | YL | 10 | BY16 | 5 | PR | 3 | 2 | 0.2 |
| Ex. 2 | MPN | 54.8 | TMP | 15 | 3002M | 5 | N865 | 5 | YL | 10 | BY16 | 5 | PR | 3 | 2 | 0.2 |
| Ex. 3 | MPN | 54.8 | TMP | 15 | 3002M | 5 | N865 | 5 | YL | 10 | BY16 | 5 | PR | 3 | 2 | 0.2 |
| Ex. 4 | MPN | 55 | TMP | 15 | 3002M | 5 | N865 | 5 | YL | 10 | BY16 | 5 | PR | 3 | 2 | 0 |
| Ex. 5 | MPN | 55 | TMP | 15 | 3002M | 5 | N865 | 5 | YL | 10 | BY16 | 5 | PR | 3 | 2 | 0 |
| Ex. 6 | MPN | 55 | TMP | 15 | 3002M | 5 | N865 | 5 | YL | 10 | BY16 | 5 | PR | 3 | 2 | 0 |
| Ex. 7 | MPN | 36.8 | 3G | 9 | 3002M | 0 | N865 | 18 | YL | 0 | BY16 | 3 | PR | 2 | 1 | 0.2 |
| Ex. 8 | MPN | 36.8 | 3G | 9 | 3002M | 0 | N865 | 18 | YL | 0 | BY16 | 3 | PR | 2 | 1 | 0.2 |
| Ex. 9 | MPN | 36.8 | 3G | 9 | 3002M | 0 | N865 | 18 | YL | 0 | BY16 | 3 | PR | 2 | 1 | 0.2 |
| Com. | MPN | 30.8 | 3G | 10 | 3002M | 0 | N865 | 20 | YL | 0 | BY16 | 4 | PR | 0 | 1 | 0.2 |
| Ex. 1 | | | | | | | | | | | | | | | | |
| Com. | MPN | 36.8 | 3G | 9 | 3002M | 0 | N865 | 18 | YL | 0 | BY16 | 3 | PR | 2 | 1 | 0.2 |
| Ex. 2 | | | | | | | | | | | | | | | | |

### Examples 1A to 8A and Comparative Examples 1A to 6A

Each of semiconductor wafer bonding products was manufactured in the same manner as Example 1, except that the absorbance index “α_{E1}” and the thickness “t₁” of the support base and the absorbance index “α_{E2}” and the thickness “t₂” of the spacer formation layer were changed as shown in Table 3.

Here, in Comparative Example 6A, a polyimide film (“upilex 25SGA” produced by UBE INDUSTRIES, LTD.) was used as the support base. Further, in Examples 5A to 8A and Comparative Examples 3A and 6A, as shown in Table 4, the absorbance index “α_{E2}” of the spacer formation layer was adjusted by changing the compounding ratio of the resin varnish used for forming the spacer formation layer.

In this regard, in Table 4, indicated are the methacryloyl-modified novolac-type bisphenol A resin as “MPN”, the trimethylol propane trimethacrylate as “TMP”, the epoxy vinyl ester resin as “3002M”, the bisphenol A novolac-type epoxy resin as “N865”, the bisphenol A-type epoxy resin as “YL”, the silicone epoxy resin as “BY16”, the phenol novolac resin as “PR” and the triethylene glycol dimethacrylate (“NKESTER3G” produced by Shin-Nakamura Chemical CO., Ltd.) as “3G”, respectively.

Further, in Example 8A and Comparative Example 5A, but not shown in Table 4, 30 wt % of the silica filler having an average particle size of 0.125 μm and a maximal particle size of 0.35 μm (“NS-3N” produced by Tokuyama Corporation) was added.

TABLE 3

| | Support base | | | Spacer formation layer | | | | | |
|---|---|---|---|---|---|---|---|---|---|
| | | AbsorbAnce | | | AbsorbAnce | | Spacer | | |
| | | index | | | index | | formation film | | |
| | Exposure | to | | Exposure | to | | | Exposure | |
| | light | exposure | Average | light | exposure | Average | | light | |
| | transmission | light | thickness | transmission | light | thickness | | transmission | Evaluation |
| | T_{E1} | α_{E1} | t₁ | T_{E2} | α_{E2} | t₂ | α_{E1} · αt₁ + | T_{E} | Under- |
| | [%] | [1/μm] | [μm] | [%] | [1/μm] | [μm] | α_{E2} · αt₂ | [%] | cut |
| Ex. 1A | 83.9 | 0.002 | 38 | 89.5 | 0.0096 | 5 | 0.124 | 75.2 | A |
| Ex. 2A | 63.1 | 0.002 | 100 | 89.5 | 0.0096 | 5 | 0.248 | 56.5 | A |
| Ex. 3A | 83.9 | 0.002 | 38 | 33.1 | 0.0096 | 50 | 0.556 | 27.8 | B |
| Ex. 4A | 63.1 | 0.002 | 100 | 33.1 | 0.0096 | 50 | 0.68 | 20.9 | B |
| Ex. 5A | 63.1 | 0.002 | 100 | 98.1 | 0.0017 | 5 | 0.2085 | 61.9 | A |
| Ex. 6A | 63.1 | 0.002 | 100 | 67.6 | 0.0017 | 100 | 0.37 | 42.7 | A |
| Ex. 7A | 83.9 | 0.002 | 38 | 25.4 | 0.0017 | 350 | 0.671 | 21.3 | B |
| Ex. 8A | 83.9 | 0.002 | 38 | 65.3 | 0.037 | 5 | 0.261 | 54.8 | A |
| Com. | 39.8 | 0.002 | 200 | 33.1 | 0.0096 | 50 | 0.88 | 13.2 | D |
| Ex. 1A | | | | | | | | | |
| Com. | 83.9 | 0.002 | 38 | 11.0 | 0.0096 | 100 | 1.036 | 9.2 | D |
| Ex. 2A | | | | | | | | | |
| Com. | 63.1 | 0.002 | 100 | 25.4 | 0.0017 | 350 | 0.795 | 16.0 | D |
| Ex. 3A | | | | | | | | | |
| Com. | 97.7 | 0.002 | 5 | 14.1 | 0.0017 | 500 | 0.86 | 13.8 | D |
| Ex. 4A | | | | | | | | | |
| Com. | 83.9 | 0.002 | 38 | 1.4 | 0.037 | 50 | 1.926 | 1.2 | D |
| Ex. 5A | | | | | | | | | |
| Com. | 0.3 | 0.1 | 25 | 98.1 | 0.0017 | 5 | 2.5085 | 0.3 | D |
| Ex. 6A | | | | | | | | | |

TABLE 4

| | Spacer formation film | | | | | | | | | | | | | | | |
|---|---|---|---|---|---|---|---|---|---|---|---|---|---|---|---|---|
| | Constituent material of resin composition constituting spacer formation layer | | | | | | | | | | | | | | | |
| | | | | | | | | | | | | | | | Photo | |
| | | | | | | | | | | | | | | | Polym- | |
| | Alkali | | | | | | | | | | | | | | eriza- | Ultra- |
| | Soluble | | | | | | | | | | | | | | tion | violet |
| | resin | | Photo polymerizable resin | | | | Thermosetting resin | | | | | | | | initiator | absorber |
| | | Amount | | Amount | | Amount | | Amount | | Amount | | Amount | | Amount | Amount | Amount |
| | Kind | [wt %] | Kind | [wt %] | Kind | [wt %] | Kind | [wt %] | Kind | [wt %] | kind | [wt %] | kind | [wt %] | [wt %] | [wt %] |
| Ex. 1A | MPN | 54.8 | TMP | 15 | 3002M | 5 | N865 | 5 | YL | 10 | BY16 | 5 | PR | 3 | 2 | 0.2 |
| Ex. 2A | MPN | 54.8 | TMP | 15 | 3002M | 5 | N865 | 5 | YL | 10 | BY16 | 5 | PR | 3 | 2 | 0.2 |
| Ex. 3A | MPN | 54.8 | TMP | 15 | 3002M | 5 | N865 | 5 | YL | 10 | BY16 | 5 | PR | 3 | 2 | 0.2 |
| Ex. 4A | MPN | 54.8 | TMP | 15 | 3002M | 5 | N865 | 5 | YL | 10 | BY16 | 5 | PR | 3 | 2 | 0.2 |
| Ex. 5A | MPN | 55 | TMP | 15 | 3002M | 5 | N865 | 5 | YL | 10 | BY16 | 5 | PR | 3 | 2 | 0 |
| Ex. 6A | MPN | 55 | TMP | 15 | 3002M | 5 | N865 | 5 | YL | 10 | BY16 | 5 | PR | 3 | 2 | 0 |
| Ex. 7A | MPN | 55 | TMP | 15 | 3002M | 5 | N865 | 5 | YL | 10 | BY16 | 5 | PR | 3 | 2 | 0 |
| Ex. 8A | MPN | 36.8 | 3G | 9 | 3002M | 0 | N865 | 18 | YL | 0 | BY16 | 3 | PR | 2 | 1 | 0.2 |
| Com. | MPN | 54.8 | TMP | 15 | 3002M | 5 | N865 | 5 | YL | 10 | BY16 | 5 | PR | 3 | 2 | 0.2 |
| Ex. 1A | | | | | | | | | | | | | | | | |
| Com. | MPN | 54.8 | TMP | 15 | 3002M | 5 | N865 | 5 | YL | 10 | BY16 | 5 | PR | 3 | 2 | 0.2 |
| Ex. 2A | | | | | | | | | | | | | | | | |
| Com. | MPN | 55 | TMP | 15 | 3002M | 5 | N865 | 5 | YL | 10 | BY16 | 5 | PR | 3 | 2 | 0 |
| Ex. 3A | | | | | | | | | | | | | | | | |
| Com. | MPN | 55 | TMP | 15 | 3002M | 5 | N865 | 5 | YL | 10 | BY16 | 5 | PR | 3 | 2 | 0 |
| Ex. 4A | | | | | | | | | | | | | | | | |
| Com. | MPN | 36.8 | 3G | 9 | 3002M | 0 | N865 | 18 | YL | 0 | BY16 | 3 | PR | 2 | 1 | 0.2 |
| Ex. 5A | | | | | | | | | | | | | | | | |
| Com. | MPN | 55 | TMP | 15 | 3002M | 5 | N865 | 5 | YL | 10 | BY16 | 5 | PR | 3 | 2 | 0 |
| Ex. 6A | | | | | | | | | | | | | | | | |

### [2] Evaluation

[2-1] Evaluation of Ease of Mask Alignment

When the semiconductor wafer bonding product was manufactured in each of Examples 1 to 9 and Comparative Examples 1 and 2, the semiconductor wafer with the spacer formation film was visually observed, and then ease of mask alignment thereof was evaluated based on the following evaluation criteria.

A: The alignment marks provided on the semiconductor wafer could be visually confirmed through the support base and the spacer formation layer very clearly.

B: The alignment marks provided on the semiconductor wafer were slightly obscured, but could be visually confirmed through the support base and the spacer formation layer at such a degree as a problem would not practically occur.

C: The alignment marks provided on the semiconductor wafer could not be visually confirmed through the support base and the spacer formation layer clearly, and therefore a problem practically would occur.

D: The alignment marks provided on the semiconductor wafer were impossible to be visually confirmed through the support base and the spacer formation layer.

[2-2] Evaluation of Crack Generation Due to Undercut

In each of Examples and Comparative Examples, 100 semiconductor wafer bonding products were manufactured as described above, respectively. The following evaluation was carried out.

Shapes of the spacers of the 100 semiconductor wafer bonding products manufactured in each of Examples and Comparative Example were observed using an electronic microscope (5,000 folds), and then a patterning property by exposure (degree of crack generation due to undercut) was evaluated based on the following evaluation criteria.

A: All the 100 spacers have no cracks or the like, and therefore have been patterned at a high patterning accuracy.

B: Among the 100 spacers, 1 to 10 spacers have cracks or the like, but have been patterned at such a patterning accuracy as a problem does not practically occur.

C: Among the 100 spacers, 11 to 20 spacers have cracks or the like, and therefore have not been patterned at a sufficient patterning accuracy.

D: Among the 100 spacers, 21 or more spacers have cracks or the like, and therefore have been patterned at a low patterning accuracy.

These evaluation results are shown in Tables 1 and 3.

As shown in Table 1, the semiconductor wafer bonding product of the present invention manufactured in each of Examples 1 to 9 has superior ease of mask alignment and an excellent dimensional accuracy.

Further, the semiconductor device manufactured using the semiconductor wafer bonding product of the present invention has especially high reliability.

On the other hand, the semiconductor wafer bonding product manufactured in each of Comparative Examples 1 and 2 has inferior ease of mask alignment and does not have a sufficient patterning accuracy by the exposure.

Further, as shown in Table 3, in the semiconductor wafer bonding product of the present invention manufactured in each of Examples 1A to 8A, the spacer has no cracks or the like and an excellent dimensional accuracy. Further, the semiconductor device manufactured using the semiconductor wafer bonding product of the present invention has especially high reliability.

On the other hand, in each of Comparative Examples 1A to 6A, the patterning accuracy by the exposure is not sufficiently.

### INDUSTRIAL APPLICABILITY

A spacer formation film of the present invention includes a support base having a sheet-like shape; and a spacer formation layer provided on the support base and having a photo curable property, the spacer formation layer capable of forming a spacer provided between a transparent substrate and a semiconductor wafer by being exposed and developed, wherein in the case where an average thickness of the support base is defined as t₁ (μm), an average thickness of the spacer formation layer is defined as t₂ (μm), an absorbance index of the support base within wavelength band of visible light is defined as α_{V1} (1/μm) and an absorbance index of the spacer formation layer within the wavelength band of the visible light is defined as α_{V2} (1/μm), each of the following relational expressions <1> to <4> is satisfied.

α_{V1}×t₁+α_{V2}×t₂≦−log₁₀(0.2) <1>

5≦t₁≦200 <2>

5≦t₂≦400 <3>

10≦t₁+t₂≦405 <4>

This makes it possible to manufacture a semiconductor wafer bonding product in which the semiconductor wafer and the transparent substrate are bonded together through a spacer having an excellent dimensional accuracy. Such a present invention provides industrial applicability.

What is claimed is:

1. A spacer formation film, comprising:
a support base having a sheet-like shape; and
a spacer formation layer provided on the support base and having a photo curable property, the spacer formation layer capable of forming a spacer to be provided between a transparent substrate and a semiconductor wafer by being exposed and developed,
wherein in the case where an average thickness of the support base is defined as t₁ (μm), an average thickness of the spacer formation layer is defined as t₂ (μm), an absorbance index of the support base within wavelength band of visible light is defined as α_{V1} (1/μm) and an absorbance index of the spacer formation layer within the wavelength band of the visible light is defined as α_{V2} (1/μm), each of the following relational expressions <1> to <4> is satisfied.
α_{V1}×t₁+α_{V2}×t₂≦−log₁₀(0.2) <1>
5≦t₁≦200 <2>
5≦t₂≦400 <3>
10≦t₁+t₂≦405 <4>

2. The spacer formation film as claimed in claim 1, wherein in the case where an amount of the visible light incidence into the support base is defined as I_{V0}, an amount of the visible light passed through the support base is defined as I_{V1} and an amount of the visible light further passed through the spacer formation layer is defined as I_{V2}, each of the following relational expressions <5> to <7> is satisfied.
I_{V1}/I_{V0}≧0.2 <5>
I_{V2}/I_{V1}≧0.2 <6>
I_{V2}/I_{V0}≧0.2 <7>

3. The spacer formation film as claimed in claim 1, wherein in the case where an absorbance index of the support base within wavelength band of an exposure light used in the exposure is defined as α_{E1} (1/μm) and an absorbance index of the spacer formation layer within the wavelength band of the exposure light is defined as α_{E2} (1/μm), each of the following relational expressions <8> to <11> is satisfied.
α_{E1}×t₁+α_{E2}×t₂≦−log₁₀(0.2) <8>
5≦t₁≦100 <9>
5≦t₂≦350 <10>
10≦t₁+t₂≦400 <11>

4. A spacer formation film, comprising:
a support base having a sheet-like shape; and
a spacer formation layer provided on the support base and having a photo curable property, the spacer formation layer capable of forming a spacer to be provided between a transparent substrate and a semiconductor wafer by being exposed and developed,
wherein in the case where an average thickness of the support base is defined as t₁ (μm), an average thickness of the spacer formation layer is defined as t₂ (μm), an absorbance index of the support base within wavelength band of an exposure light used in the exposure is defined as α_{E1} (1/μm) and an absorbance index of the spacer formation layer within the wavelength band of the exposure light is defined as α_{E2} (1/μm), each of the following relational expressions <8> to <11> is satisfied.
α_{E1}×t₁+α_{E2}×t₂≦−log₁₀(0.2) <8>
5≦t₁≦100 <9>
5≦t₂≦350 <10>
10≦t₁+t₂≦400 <11>

5. The spacer formation film as claimed in claim 3, wherein in the case where an amount of the exposure light incidence into the support base is defined as I_{E0}, an amount of the exposure light passed through the support base is defined as I_{E1} and an amount of the exposure light further passed through the spacer formation layer is defined as I_{E2}, each of the following relational expressions <12> to <14> is satisfied.
I_{E1}/I_{E0}≧0.2 <12>
0.1≦I_{E2}/I_{E1}≦0.9 <13>
0.1≦I_{E2}/I_{E0}≦0.9 <14>

6. The spacer formation film as claimed in claim 1, wherein the support base is formed of a resin material as a major component thereof.

7. The spacer formation film as claimed in claim 6, wherein the resin material comprises polyethylene, polypropylene or polyethylene terephthalate.

8. The spacer formation film as claimed in claim 1, wherein the spacer formation layer is formed of a material containing an alkali soluble resin, a thermosetting resin and a photo initiator.

9. The spacer formation film as claimed in claim 8, wherein the alkali soluble resin is a (meth)acryl-modified phenol resin.

10. The spacer formation film as claimed in claim 8, wherein the thermosetting resin is an epoxy resin.

11. A method of manufacturing a semiconductor wafer bonding product, comprising:
a step of preparing the spacer formation film defined by claim 1;
a step of attaching the spacer formation layer to a semiconductor wafer having one surface from a side of the one surface;
a step of subjecting the spacer formation layer to an exposure treatment by being selectively irradiated with an exposure light through the support base;
a step of removing the support base;
a step of forming a spacer by subjecting the spacer formation layer to a developing treatment using a developer; and
a step of bonding a transparent substrate to a surface of the spacer opposite to the semiconductor wafer.

12. A method of manufacturing a semiconductor wafer bonding product, comprising:
a step of preparing the spacer formation film defined by claim 1;
a step of attaching the spacer formation layer to a transparent substrate having one surface from a side of the one surface;
a step of subjecting the spacer formation layer to an exposure treatment by being selectively irradiated with an exposure light through the support base;
a step of removing the support base;
a step of forming a spacer by subjecting the spacer formation layer to a developing treatment using a developer; and
a step of bonding a semiconductor wafer to a surface of the spacer opposite to the transparent substrate.

13. The method as claimed in claim 11 or 12, wherein when the spacer formation layer is irradiated with the exposure light through the support base, the irradiation of the exposure light is carried out through a mask placed at a side of the support base opposite to the spacer formation layer.

14. The method as claimed in claim 13, wherein when the mask is placed, positioning of the mask is carried out using an alignment mark provided on the mask and an alignment mark provided on the semiconductor wafer or the transparent substrate located at a side of the spacer formation layer opposite to the support base.

15. The method as claimed in claim 13, wherein a distance between the mask and the support base during the exposure step is preferably in the range of 0 to 2,000 μm.

16. A semiconductor wafer bonding product manufactured using the method defined by claim 11.

17. A semiconductor wafer bonding product in which a semiconductor wafer and a transparent substrate are bonded together through a spacer formed using the spacer formation film defined by claim 1.

18. A semiconductor device obtained by dicing the semiconductor wafer bonding product defined by claim 16.
